(19) United States
(12) Patent Application Publication
(10) Pub. No.: US 2026/0335888 A1
(43) Pub. Date: Oct. 29, 2026

(54) ACOUSTOFLUIDIC DEVICE, SYSTEM AND METHODS OF MAKING THE SAME

(71) Applicant: University of Hawai'i, Honolulu, HI (US)

(72) Inventors: Tyler Ray, Honolulu, HI (US); Roxanne Kate Balanay, Honolulu, HI (US); Justin Yip, Honolulu, HI (US)

(21) Appl. No.: 19/657,883

(22) Filed: Apr. 24, 2026

Related U.S. Application Data
(60) Provisional application No. 63/794,274, filed on Apr. 24, 2025.

(51) Int. Cl. B01L 3/00; B81B 1/00

(52) U.S. Cl. CPC B01L 3/50273; B81B 1/006; B01L 2200/025; B01L 2200/027; B01L 2200/0636; B01L 2200/0647; B01L 2200/12; B01L 2300/0858; B01L 2300/0883; B01L 2300/1894; B01L 2400/0436; B81B 2201/051; B81B 2203/0338; B81B 2203/0392

(57) ABSTRACT

An acoustofluidic device and system are disclosed that integrate micromixing and particle focusing within a single microfluidic platform. The device comprises a monolithic microfluidic chip having an inlet portion, a mixing portion with protrusions configured to induce acoustic streaming, a focusing portion configured to establish a standing acoustic wave, and an outlet portion for separating collected and waste components. Geometric features, including channel dimensions and layer thicknesses, are selectively configured to produce distinct acoustofluidic behaviors in different regions under a single acoustic excitation. In some embodiments, the device is fabricated using additive manufacturing, enabling complex three-dimensional channel architectures in low-acoustic-impedance materials. Methods of making and using the device and system are also disclosed, including controlling acoustic parameters and temperature to achieve consistent mixing and focusing performance for applications such as biochemical assays and particle manipulation.

### CROSS-REFERENCE TO RELATED APPLICATIONS

This application claims priority to U.S. Provisional Application No. 63/794,274 filed on Apr. 24, 2025, incorporated herein by reference in its entirety.

### STATEMENT REGARDING FEDERALLY SPONSORED RESEARCH OR DEVELOPMENT

This invention was made with government support under N000142512338 provided by the Office of Naval Research, W911NF-23-1-0162 and W911NF-24-1-0278 provided by the Army Research Office, CMMI2440170 and 2229784 provided by the National Science Foundation, P20 GM113134 provided by the National Institutes of Health, and 80NSSC23K1210 provided by the National Aeronautics and Space Administration. The government has certain rights in the invention.

### BACKGROUND OF THE INVENTION

Lab-on-chip technologies have been developed to perform fluid manipulation, mixing, and particle handling within compact microfluidic platforms. However, achieving multiple fluidic functions within a single device remains challenging. In particular, different acoustofluidic phenomena require distinct geometric and material conditions to operate effectively. For example, acoustic streaming used for mixing and standing acoustic waves used for particle focusing rely on different structural configurations, including variations in channel geometry and surrounding layer thicknesses. As a result, integrating these functions into a single device without compromising performance presents a significant design challenge.

Existing lab-on-chip devices often rely on separate components or distinct operating conditions to achieve mixing and particle focusing, which can increase system complexity. Additionally, devices fabricated from polymer materials may exhibit reduced acoustic reflection compared to traditional materials, making it more difficult to establish resonance conditions necessary for particle focusing. While channel dimensions may be selected to support standing wave formation, unintended acoustic effects can occur in regions where such behavior is not desired.

Thus, there is a need for microfluidic devices that can reliably support multiple acoustofluidic functions within a single structure while maintaining precise control over acoustic behavior in different regions of the device.

### SUMMARY OF THE INVENTION

Aspects of the disclosure relate to an acoustofluidic system including a microfluidic device having a body with a first end and a second end, an inlet portion in the first end of the body having openings forming first and second inlets, and first and second conduits fluidly connected to the first and second inlets, respectively, a mixing portion in the body having a mixing channel fluidly connected to the first and second conduits, wherein the mixing portion comprises a bottom layer, a top layer and sidewalls forming the mixing channel therein, and a plurality of protrusions extending out from the sidewalls into the interior of the mixing channel, a focusing portion in the body having a focusing channel fluidly connected to the mixing channel, wherein the focusing portion comprises a bottom layer, a top layer, and sidewalls forming the focusing channel therein, and an outlet portion in the second end of the body having an outlet region fluidly connected to the focusing channel, and one or more openings forming one or more outlets fluidly connected to the outlet region, wherein a thickness of the bottom layer of the mixing portion is greater than a thickness of the bottom layer of the focusing portion, and a transducer configured to apply acoustic energy to the microfluidic device, wherein upon application of the acoustic energy, fluid is mixed via acoustic streaming in the mixing channel, and particles are focused via a standing acoustic wave in the focusing channel.

In some embodiments, a thickness of the top layer of the focusing portion is greater than the thickness of the bottom layer of the focusing portion. In some embodiments, a ratio between the thickness of the top layer of the focusing portion and the thickness of the bottom layer of the focusing portion is 1.5:1. In some embodiments, the thickness of the bottom layer of the mixing portion is at least twice the thickness of the bottom layer of the focusing portion. In some embodiments, the width of each sidewall of the focusing portion is greater than the thicknesses of the top and bottom layers of the focusing portion.

In some embodiments, a width of the focusing channel is selected based on at least one of an acoustic wavelength corresponding to the acoustic energy to establish the standing acoustic wave within the focusing channel, and a speed of sound of the liquid. In some embodiments, the width of the focusing channel is half of the acoustic wavelength.

In some embodiments, the plurality of protrusions are arranged in a staggered pattern in the mixing channel. In some embodiments, each protrusion in the plurality of protrusions comprises a tip angle of less than 40°.

In some embodiments, the microfluidic device further includes a transition portion in the body having a transition channel fluidly connecting the mixing channel and the focusing channel, wherein the transition portion comprises a bottom layer, a top layer, and sidewalls forming the transition channel therein, and wherein the bottom layer of the transition portion tapers from a first thickness to a second thickness. In some embodiments, the first thickness is the same as the thickness of the bottom layer of the mixing portion, and the second thickness is the same as the thickness of the bottom layer of the focusing portion.

In some embodiments, the mixing portion comprises a curved structure positioned at least partially over the focusing portion, and wherein the mixing channel extends through the curved structure out of plane of the focusing channel. In some embodiments, the curved structure comprises first and second curved portions, each portion extending from a first side to a second side of the focusing portion.

In some embodiments, the outlet region comprises a plurality of conduits fluidly connected to the one or more outlets, and the one or more outlets comprise first and second outlets. In some embodiments, a first conduit of the plurality of conduits is fluidly connected to the first outlet, and second and third conduits are fluidly connected to the second outlet. In some embodiments, an opening of the first conduit is aligned with an axis extending along the length of the focusing channel, and openings of the second and third conduits are not aligned with the axis. In some embodiments, at least one conduit of the plurality of conduits comprises a serpentine structure.

In some embodiments, the body is formed from a monolithic structure of a low-acoustic impedance polymer resin or a photopolymer resin fabricated via additive manufacturing. In some embodiment, the system further includes a cooling block contacting at least one of the transducer and the microfluidic system. In some embodiments, the transducer is configured such that a single acoustic excitation simultaneously produces acoustic streaming in the mixing channel and the standing acoustic wave in the focusing channel, wherein the standing acoustic wave is a half-standing acoustic wave.

### BRIEF DESCRIPTION OF THE DRAWINGS

The following detailed description of embodiments of the invention will be better understood when read in conjunction with the appended drawings. It should be understood, however, that the invention is not limited to the precise arrangements and instrumentalities of the embodiments shown in the drawings.

FIG. 1A is an image of an exemplary acoustic mixing and focusing microfluidic device, also referred to as an “acoustofluidic” device, according to aspects of the present disclosure.

FIG. 1B is an image of another exemplary acoustofluidic device according to aspects of the present disclosure.

FIG. 1C is an image of an exemplary acoustic focusing stage or portion for an acoustofluidic device according to aspects of the present disclosure.

FIG. 1D is an image showing a front cross-sectional view of an exemplary acoustic focusing portion.

FIG. 1E is an image showing a side cross-sectional view of an exemplary acoustic focusing portion.

FIG. 1F is an image showing a top cross-sectional view of an exemplary acoustic focusing portion.

FIG. 1G is a schematic of fluid and particle distribution in an exemplary acoustic mixing portion for an acoustofluidic device according to aspects of the present disclosure.

FIG. 1H is a schematic of fluid and particle distribution in an acoustic focusing portion.

FIG. 1I is an image of an exemplary outlet portion for an acoustofluidic device according to aspects of the present disclosure.

FIG. 1J is an image depicting an exemplary integrated acoustic mixing and focusing system, also referred to as an “acoustofluidic” or “acoustophoresis” system, comprising a microfluidic chip, a transducer, and a cooling block according to aspects of the present disclosure.

FIG. 1K is a diagram depicting an exemplary acoustofluidic system according to aspects of the disclosure.

FIG. 1L is an image of an exemplary acoustofluidic system configured for an enzyme-linked affinity assay according to aspects of the present disclosure.

FIG. 1M is an image of an exemplary acoustofluidic system under UV light.

FIG. 1N depicts an exemplary computer architecture for a computer according to aspects of the disclosure.

FIG. 2A is an image of an exemplary resin 3D-printed micromixer (e.g., an inlet portion and an acoustic mixing portion) featuring spikes within the channel.

FIG. 2B is an image of an exemplary channel interior for an acoustic mixing portion showing staggered spikes with numbering, wherein the dark red dashed line indicates the analysis location at the midpoint between adjacent spikes.

FIG. 2C is a plot of mixing index (MI) at three flow rates (3, 6, and 9 μL/min) measured between spikes 10 and 11 (as shown in FIG. 2B).

FIG. 2D is a plot of MI at 9 μL/min across spike numbers during experimental acquisition.

FIG. 2E is representative microscopy images of an exemplary micromixer at different times, wherein scale bars represent 750 μm.

FIG. 2F is a plot of MI at 9 μL/min in the region of interest over time, wherein the magenta dashed line indicates the moment acoustics were enabled, while black, red, and blue solid lines represent images extracted in FIG. 2E.

FIG. 3A is an image of an exemplary focusing portion with a straight channel.

FIG. 3B is a side-view schematic of an exemplary focusing portion showing varying thicknesses of the bottom (t_{bottom}) and top (tₜₒₚ) layers.

FIG. 3C is an image showing black polyethylene microspheres suspended in silicone oil in a focusing portion, imaged with acoustics off and on, wherein scale bars represent 750 μm.

FIG. 3D is an image showing orange fluorescent polymer microspheres suspended in fluorescein salt solution in a focusing stage or portion, imaged with acoustics off and on, wherein scale bars represent 750 μm.

FIG. 4A is an image of an exemplary acoustic mixing and focusing microfluidic device.

FIG. 4B is a side-view schematic of exemplary stages or portions for an acoustic mixing and focusing microfluidic device showing three stages and varying bottom thicknesses.

FIG. 4C is an image showing orange fluorescent polymer microspheres suspended in fluorescein salt solution and blue-dyed DI water co-flowed through an exemplary acoustic mixing and focusing device.

FIG. 4D is an image showing a mixing portion of an exemplary acoustic mixing and focusing device imaged with acoustics off and on, wherein scale bars represent 750 μm.

FIG. 4E is an image of a focusing portion of an exemplary acoustic mixing and focusing device imaged with acoustics off and on, wherein scale bars represent 750 μm.

FIG. 5A is an image of an exemplary acoustic mixing and focusing microfluidic device according to aspects of the disclosure.

FIG. 5B is fluorescence images of the mixing portion with acoustics off and on, wherein scale bars represent 750 μm.

FIG. 5C is bright-field images of the focusing portion of an exemplary integrated acoustic mixing and focusing device with acoustics off and on.

FIG. 5D is a plot of absorbance measurements comparing standard process (ELISA), device performance in absence (Acoustic Off) and presence (Acoustic On; 20 Vpp) of acoustophoretic mixing/focusing, wherein scale bars represent 750 μm.

FIGS. 6A & 6B are plots of MI at three spatial positions in the device without and with acoustic mixing for two flow rates: (FIG. 6A) 3 μL/min, (FIG. 6B) 6 μL/min.

FIGS. 6C & 6D are plots showing MI at (FIG. 6C) 3 μL/min and (FIG. 6D) 6 μL/min in the region of interest over time, wherein the magenta dashed line indicates the time of acoustic field application.

FIG. 6E is an experimental image showing the masking process used to calculate the MI within the ROI.

FIGS. 7A & 7B are images showing various top and bottom thicknesses of exemplary acoustic focusing portions experiencing different applied voltages during thickness and voltage tunings.

FIGS. 7C & 7D are images showing exemplary printed chips with the original nominal and compensated thicknesses.

### DETAILED DESCRIPTION

The following discussion omits or only briefly describes conventional features of microfluidic and acoustofluidic systems, devices and methods that are apparent to those skilled in the art. Those of ordinary skill in the pertinent arts may thus recognize that other elements may be desirable and/or necessary to implement the devices, systems, and/or methods described herein. It is noted that various embodiments are described in detail with reference to the drawings. Reference to these various embodiments does not limit the scope of the claims attached hereto. Additionally, any embodiments set forth in this specification are intended to be non-limiting and merely set forth some of the many possible implementations for the appended claims. Further, particular features described herein can be used in combination with other described features in each of the various possible combinations and permutations. As such, it is understood that this detailed description is exemplary and explanatory only and is not restrictive of the broad inventive concepts upon which the embodiments disclosed herein are based.

Unless otherwise specifically defined herein, all terms are to be given their broadest reasonable interpretation. This includes meanings implied from the specification as well as meanings understood by those skilled in the art and/or as defined in dictionaries, treatises, etc.

It is noted that, as used in this specification and the appended claims, the singular forms “a,” “an,” and “the” include plural referents unless otherwise specified. The term “includes” and/or “including,” when used in this specification, specify the presence of stated features, elements, and/or components, but do not preclude the presence or addition of one or more other features, steps, operations, elements, components, and/or groups thereof.

Relative terms such as “horizontal,” “vertical,” “up,” “down,” “top,” and “bottom” as well as derivatives thereof (e.g., “horizontally,” “downwardly,” “upwardly,” etc.) should be construed to refer to the orientation as then-described or as shown in the drawing figure under discussion. These relative terms are for convenience of description and normally are not intended to require a particular orientation in actuality. Terms including “inwardly” versus “outwardly,” “longitudinal” versus “lateral,” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The phrases “operatively” or “operably connected” indicates such an attachment, coupling, or connection that allows the pertinent structures to operate as intended by virtue of that relationship.

Reference throughout the specification to “one embodiment,” “an embodiment,” or “some embodiments” means that a particular feature, structure, or characteristic described in connection with at least one embodiment of the subject matter is included in at least one embodiment of the subject matter disclosed. Thus, the appearance of the phrases “in one embodiment,” “in an embodiment,” or “in some embodiments” in various places throughout the specification is not necessarily referring to the same embodiment. Further, the particular features, structures, or characteristics of “one embodiment,” “an embodiment,” or “some embodiments” may be combined in any suitable manner with each other to form additional embodiments of such combinations. It is intended that embodiments of the disclosed subject matter cover modifications and variations thereof. Terms such as “first,” “second,” “third,” etc., merely identify one of a number of portions, components, steps, operations, functions, and/or points of reference as disclosed herein, and likewise to not necessarily limit embodiments of the present disclosure to any particular configuration or orientation.

Moreover, throughout this disclosure, various aspects can be presented in a range format. It should be understood that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6, and any whole and partial increments therebetween. This applies regardless of the breadth of the range. As used herein, the term “about” in reference to a measurable value, such as an amount, a temporal duration, and the like, is meant to encompass the specified value or variations of plus or minus 20%, plus or minus 10%, plus or minus 5%, plus or minus 1%, and plus or minus 0.1% of the specified value, as such variations are appropriate and fit within the confines of a functional system.

The terms “proximal,” “distal,” “anterior,” “posterior,” “medial,” “lateral,” “superior,” and “inferior” are defined by their standard usage indicating a directional term of reference. For example, “proximal” refers to a position that is situated nearer to the center of a body or point of attachment or interest. In another example, “anterior” refers to the front of a body or structure, while “posterior” refers to the rear of a body or structure, in relation to a relative viewpoint. In another example, “medial” refers to the direction towards the midline of a body or structure, and “lateral” refers to the direction away from the midline of a body or structure. In some examples, “lateral” or “laterally” may refer to any sideways direction. In another example, “superior” refers to the top of a body or structure, while “inferior” refers to the bottom of a body or structure. It should be understood, however, that the directional term of reference may be interpreted within the context of a specific body or structure, such that a directional term referring to a location in the context of the reference body or structure may remain consistent as the orientation of the body or structure changes.

The terms “patient,” “subject,” “individual,” and the like are used interchangeably herein, and refer to any animal amenable to the systems, devices, and methods described herein. The patient, subject or individual may be a mammal, and in some instances, a human.

As used herein, “biocompatible” refers to any material, which, when implanted in a mammal, does not provoke an adverse response in the mammal. A biocompatible material, when introduced into an individual, is not toxic or injurious to that individual, nor does it induce immunological rejection of the material in the mammal.

Disclosed herein are acoustofluidic devices, systems, and methods of making the same. The disclosed technology combines micromixing and particle focusing functionalities into a single integrated platform. In some embodiments, variations in channel features, geometry and surrounding material thickness are configured to selectively control acoustofluidic behavior. In some embodiments, a single acoustic excitation applied to the device with a transducer produces distinct acoustofluidic behaviors in different portions of the device. In some embodiments, device geometries are selected to compensate for reduced acoustic reflection in low-acoustic-impedance materials. In some embodiments, the devices are formed from monolithic structures fabricated via additive manufacturing. Disclosed herein are particular device features, geometries, materials, layer thicknesses, and manufacturing methods that produce an integrated acoustofluidic platform particularly suited for fluid and particle mixing, and selective focusing of particles, materials, cells and/or organoids within fluids, as discussed further herein.

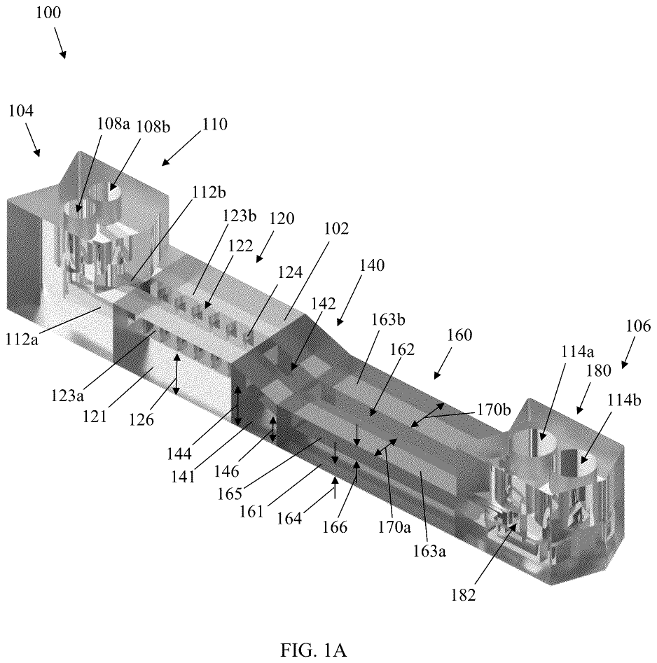

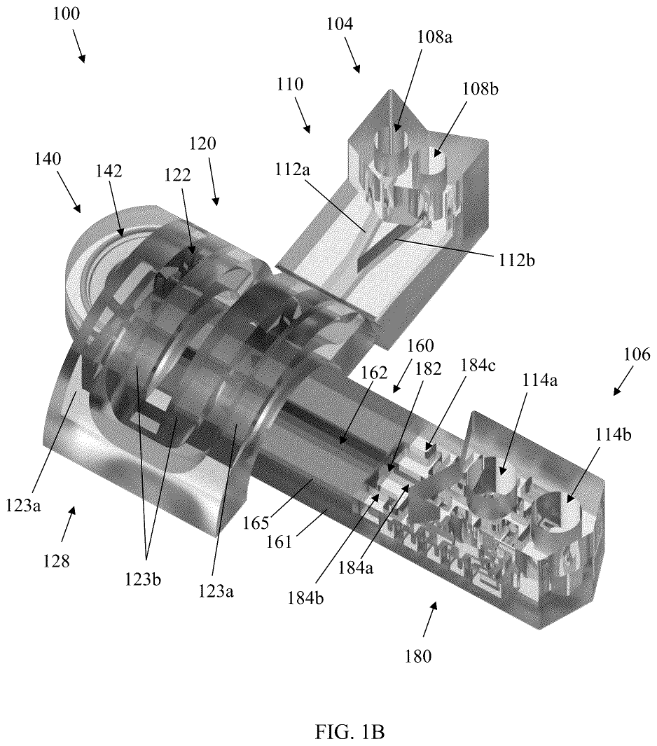

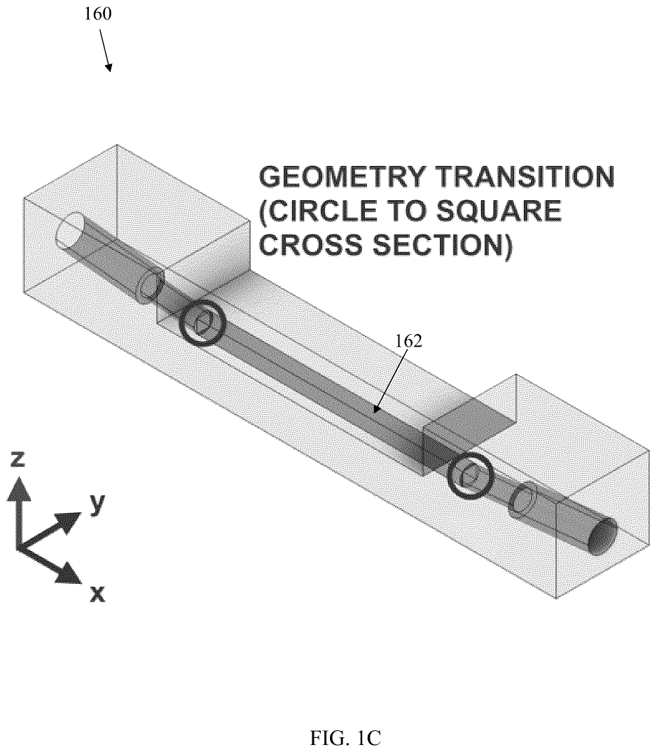

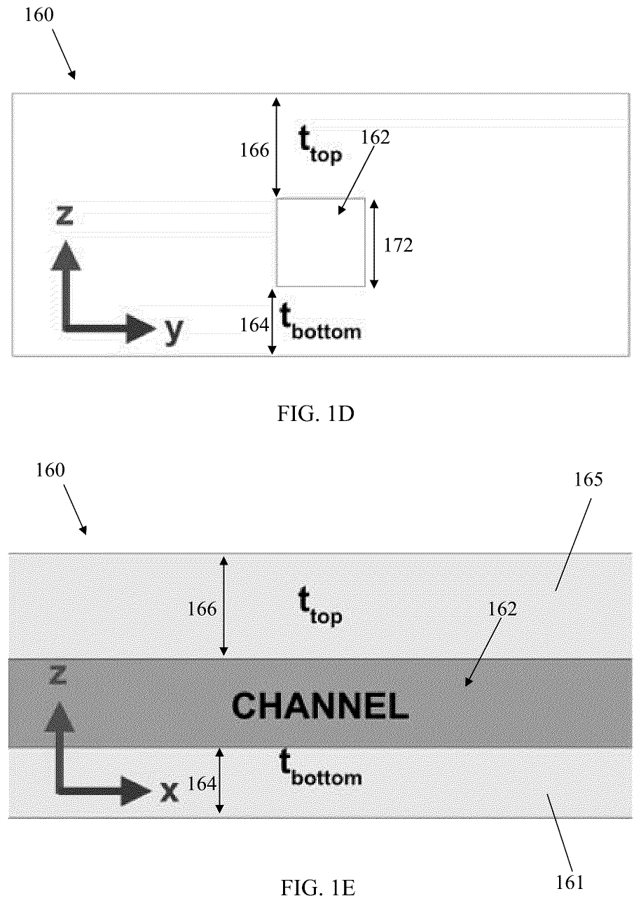

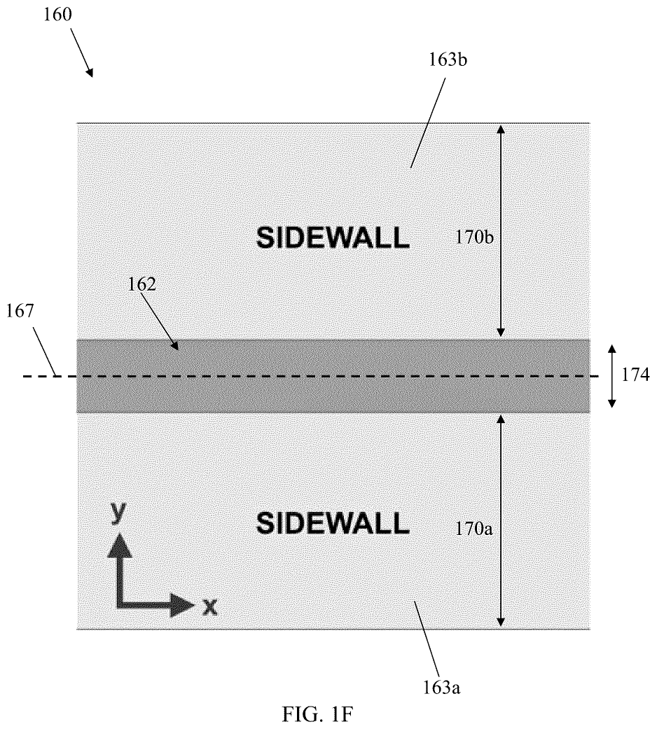

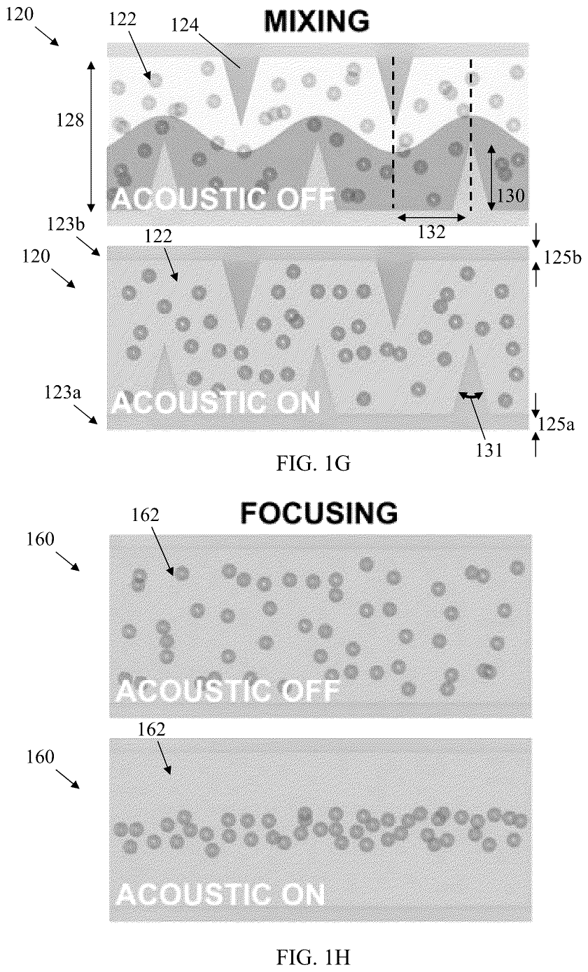

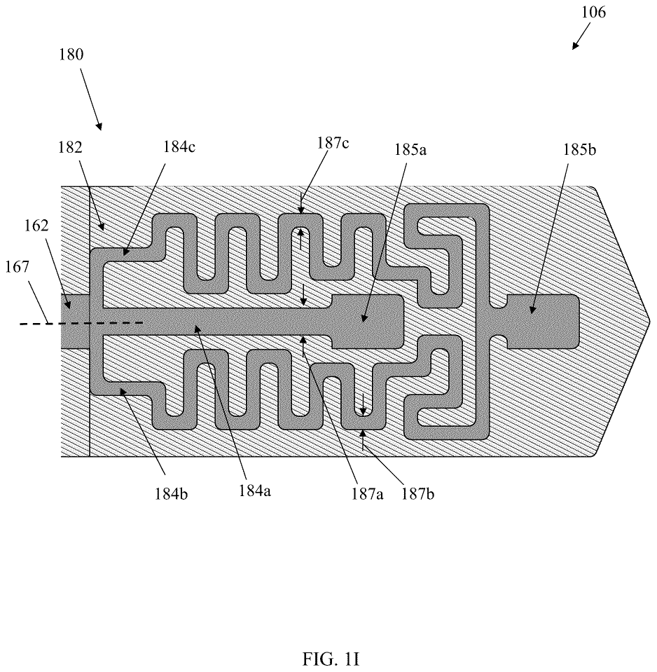

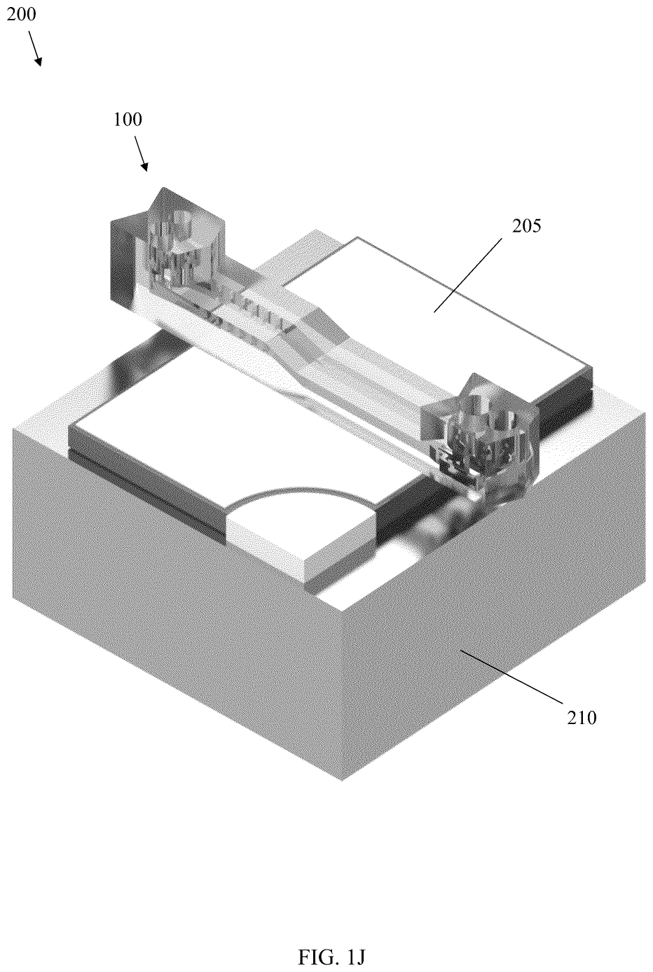

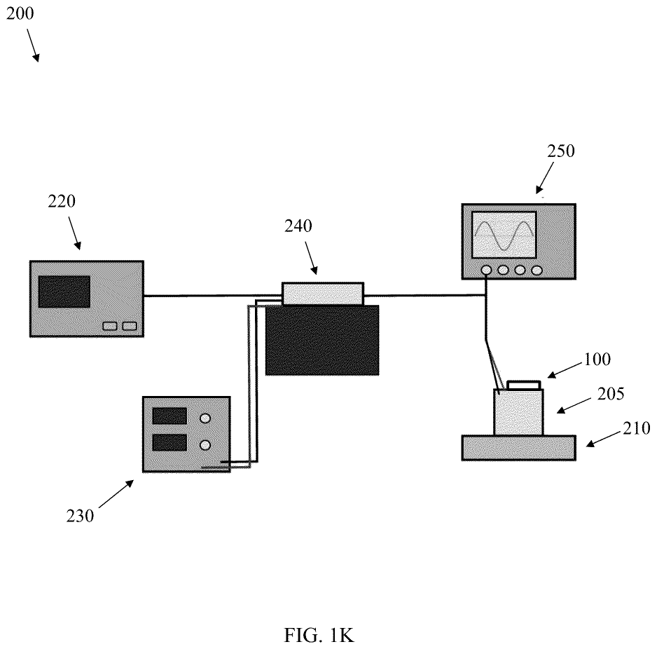

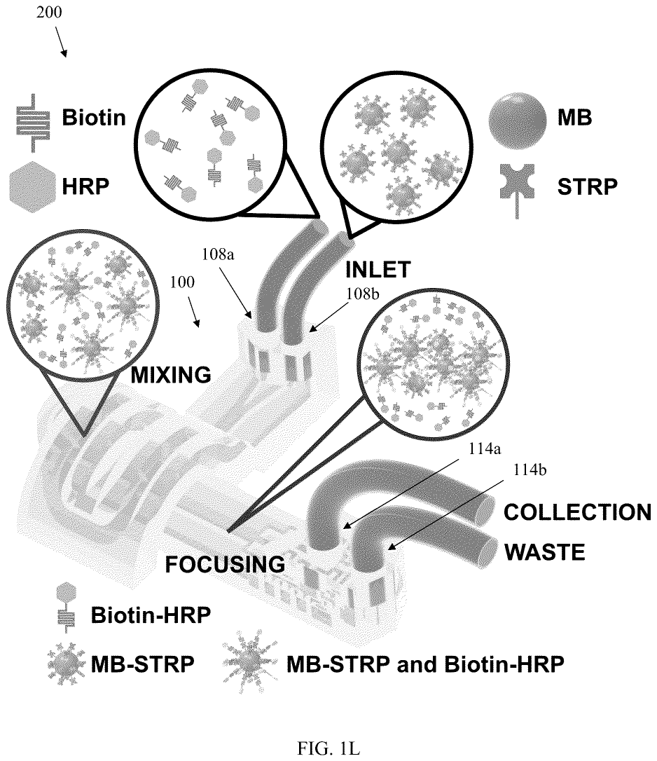

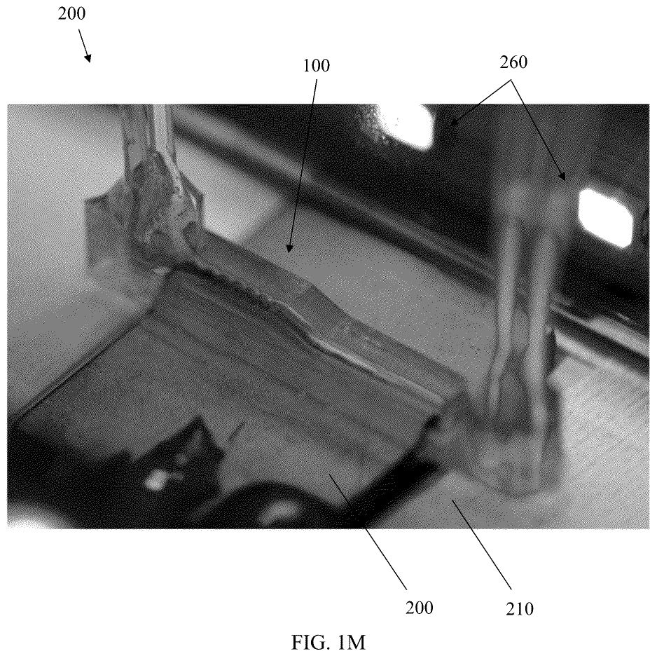

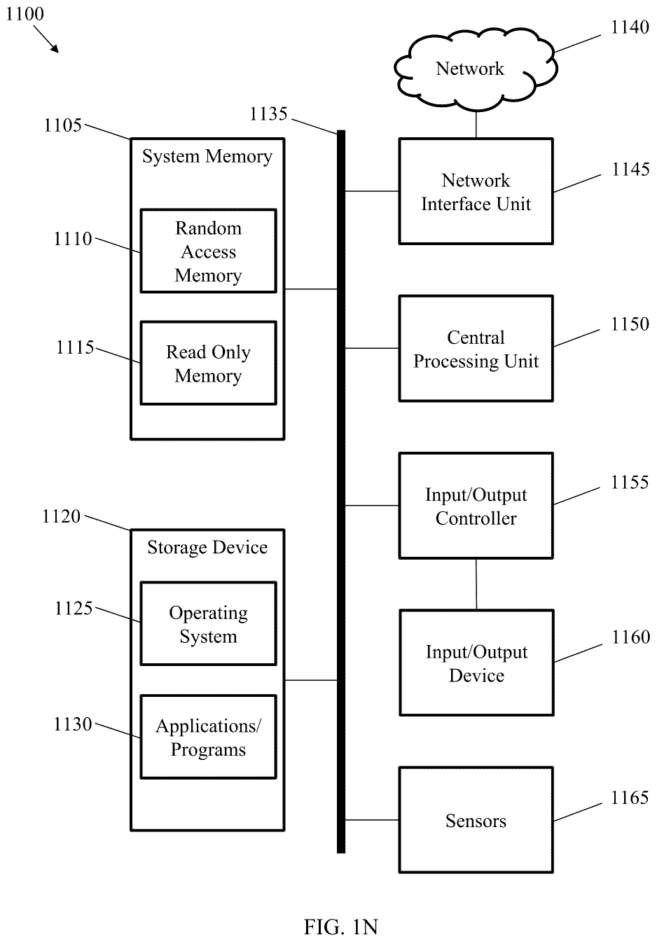

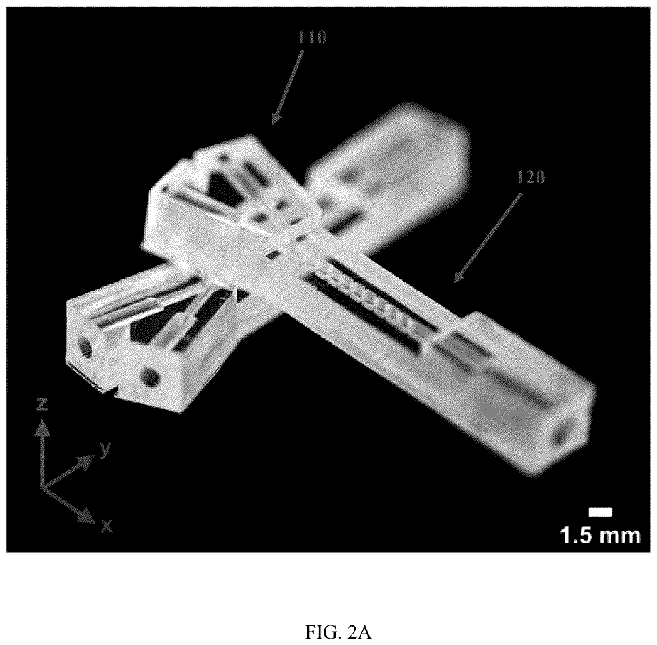

Referring now to FIG. 1A, shown is an image of an exemplary acoustic mixing and focusing microfluidic chip or device 100 according to aspects of the present disclosure. Device 100 generally comprises a body 102 having a first end 104 and a second end 106, with a plurality of fluidly connected stages, portions or regions configured to pass fluid, particles, materials, cells and/or organoids from the first end 104 to the second end 106. In some embodiments, device 100 comprises, at the first end 104, an inlet region or portion 110 comprising one or more openings forming inlets 108 (e.g., a first inlet 108a and second inlet 108b), with one or more inlet channels or conduits 112 (e.g., a first inlet conduit 112a and a second inlet conduit 112b) fluidly connected to the one or more inlets 108.

The inlet portion 110 is connected to a mixing stage or portion 120 comprising a mixing channel 122 fluidly connected to the one or more inlet conduits 112. The mixing portion 120 generally comprises a bottom layer 121 having a thickness 126, with sidewalls (123a, 123b), and a top layer forming the mixing channel 122 therein. In some embodiments, the mixing channel 122 comprises a plurality of spikes or protrusions 124 arranged in various configurations, as discussed further herein. The material(s) and thickness 126 of bottom layer 121 is calculated and/or selectively determined for particular device functionality, as discussed further herein. Optionally, in some embodiments, device 100 comprises a transition stage or portion 140 connected to mixing portion 120 and comprising a transition channel 142 fluidly connected to the mixing channel 122. The transition portion 140 generally comprises a bottom layer 141 having one or more thicknesses (e.g., a first thickness 144 and a second thickness 146), with sidewalls and a top layer forming the transition channel 142 therein.

Device 100 further comprises a focusing stage or portion 160 connected to at least one of the mixing portion 120 and the transition portion 140 comprising a focusing channel 162 fluidly connected to at least one of the mixing channel 122 and the transition channel 142. The focusing portion 160 generally comprises a bottom layer 161 having a thickness 164, sidewalls 163a, 163b, and a top layer 165 having a thickness 166, thus forming focusing channel 162 therein. The material(s) and thicknesses 164, 166 of bottom layer 161 and top layer 165, respectively, are calculated and/or selectively determined for particular device functionality, as discussed further herein.

Device 100 terminates at the second end 106 with an outlet region or portion 180 connected to the focusing portion 160 and comprising at least one outlet region or conduit 182 fluidly connected to the focusing channel 162. The outlet portion 180 comprises one or more openings forming outlets 114 (e.g., a first outlet 114a and a second outlet 114b) fluidly connected to the at least one outlet region or conduit 182. In some embodiments, the first outlet 114a is configured as a collection outlet, and the second outlet 114b is configured as a waste outlet. In some embodiments, the at least one outlet region or conduit 182 comprises one or more collection and waste separating or filtering features configured to direct or guide material to be collected to the first outlet 114a, and waste material and/or fluid to the second outlet 114b.

Referring now to FIG. 1B, shown is an image of another exemplary microfluidic chip or device 100 according to aspects of the present disclosure. As shown in the drawings, the device of FIG. 1B may comprise some or all of the features of the device of FIG. 1A. For example, the inlet portion 110, focusing portion 160 and outlet portion 180 shown in FIG. 1B may be the same, or substantially the same, as the related portions shown in FIG. 1A. The device 100 shown in FIG. 1B comprises a particularly shaped and configured mixing portion 120 and transition portion 140. In some embodiments, the mixing portion 120 comprising one or more curved or arched structures 128 that directs fluid through a bending and/or curved mixing channel 122. In some embodiments, the one or more curved or arched structures 128 are positioned over, curve over, or arch over, the focusing portion 160. In some embodiments, the mixing channel 122 comprises a first section that proceeds in an upward curved trajectory over a first side of focusing portion 160, and then down a curved trajectory to the other side of focusing portion 160. The mixing channel 122 then turns or curves about 180° and then comprises a second section that proceeds in an upward curved trajectory over the second side of focusing portion 160, and then curves down again to the first side of focusing portion 160. The mixing channel 122 then curves about 90° and connects to transition channel 142. In some embodiments, the transition channel 142 in total curves about 180° and fluidly connects the mixing channel 122 and the focusing channel 162.

The curved or arched structures 128 for mixing portion 120 are configured to reduce the size or footprint of the device while also taking advantage of complex shapes and structures formed monolithically by additive manufacturing that would be difficult or impossible to form using traditional manufacturing methods. In some embodiments, the curved or arched structure 128 does not contact focusing portion 160 and forms an air gap between mixing portion 120 and focusing portion 160. As focusing portion 160 requires specific layer thicknesses 164, 166 for proper acoustic focusing, no structure should be attached directly to top or bottoms faces of top or bottom layers 161, 165.

Referring in particular to FIG. 1I, shown is exemplary outlet portion 180 for an acoustofluidic device according to aspects of the present disclosure. Displayed are various conduits and/or fluid paths for outlet region or conduit 182. In order to separate fluid, material, particles, cells and/or organoids flowing from focusing channel 162 into outlet region or conduit 182, and then ultimately out of the first outlet 114a (e.g., collection outlet) and second outlet 114b (e.g., waste outlet) the outlet region or conduit 182 comprises one or more fluid paths, including one or more channels 184. For example, in some embodiments, the fluid flow from focusing channel 162 is split, upon entering outlet region 182, into a first conduit or channel 184a, a second conduit or channel 184b, and a third conduit or channel 184c. In some embodiments, any of the channels 184 may comprise one or more curves, bends, cavities and/or serpentine structures. In some embodiments, the second channel 184b and third channel 184c are fluidly connected to a second cavity 185b and the second outlet 114b, and the first channel 184a is fluidly connected to a first cavity 185a and the first outlet 114a. In some embodiments, second channel 184b and third channel 184c merge into second cavity 185b, and then out of second outlet 114b.

In some embodiments, first channel 184a has a width 187a that is greater than widths 187b, 187c of channels 184b, 184c, respectively. In some embodiments, second and third channels 184b, 184c each have an overall length that is greater than a length of channel 184a to increase fluid resistance. In some embodiments, an opening of the first channel 184a is aligned with an axis 167 extending along a length of the focusing channel 162, and the openings of the second channel 184b and third channel 184c are not aligned with axis 167. In some embodiments, openings of second channel 184b and third channel 184c are perpendicular to an opening of first channel 184a. The focused materials from focusing channel 162 (e.g., particles, cells, organoids) flow to first channel 184a, then to first cavity 185a, and out of outlet 114a, while excess fluid (e.g., waste, unfocused particles) is directed to second and third channels 184b, 184c, on to cavity 185b and then out of outlet 114b.

Aspects of the disclosure relate to the features, dimensions and geometries for mixing portion 120. Referring now to FIG. 1A and FIG. 1G, shown are features and dimension lines for exemplary mixing portion 120 according to aspects of the disclosure. Referring now in particular to FIG. 1A, in some embodiments, the mixing portion 120 comprises a plurality of protrusions or spikes 124 arranged in a pattern within mixing channel 122. In some embodiments, each spike 124 extends out from a position on sidewalls 123a, 123b of mixing portion 120. In some embodiments, each spike 124 spans at least a portion of a height of channel 122, or spans the entire height of the channel. In some embodiments, the plurality of spikes 124 are arranged in a staggered pattern or arrangement.

Referring now in particular to FIG. 1G, an exemplary mixing portion 120 is shown. In some embodiments, the sidewalls 123a, 123b comprise widths 125a, 125b, respectively. In some embodiments, the mixing channel 122 comprises a width 128. In some embodiments, each spike 124 comprises a height 130 and an inherent tip angle 131, and is offset from another spike 124 in the arrangement by a distance 132. In some embodiments, each height 130 is the same, or the spikes 124 may have any number of heights 130. In some embodiments, each distance 132 is the same, or the spikes 124 may be offset by any number of distance 132 and be staggered in any arrangement or configuration.

Exemplary dimensions for mixing portion 120 are disclosed herein. In some embodiments, thickness 126 of bottom layer 121 ranges between 0.01 mm and 50 mm. In some embodiments, widths 125a, 125b of sidewalls 123a, 123b, respectively, range between 0.01 mm and 50 mm. In some embodiments, widths 125a, 125b are the same, or different. In some embodiments, width 128 of channel 122 ranges between 0.001 mm and 10 mm. In some embodiments, channel 122 comprises a height ranging between 0.01 mm and 10 mm. In some embodiments, channel 122 has an overall length ranging between 1 mm and 100 mm.

In some embodiments, at least one height 130 of at least one spike in plurality of spikes 124 ranges between 0.01 mm and 10 mm. In some embodiments, at least one angle 131 of at least one spike in the plurality of spikes 124 ranges between 10° and 60°. In some embodiments, the number of spikes in plurality of spikes 124 is between 10 and 50 spikes. In some embodiments, at least one distance 132 between each spike ranges between 0.01 mm and 10 mm. In some embodiments, each spike 124 has a height 130 of about 350 μm, an angle 131 of about 30°, and a staggered spacing or distance 132 of about 750 μm, which yields 20 uniformly distributed spikes 124 in total. In some embodiments, each spike of the plurality of spikes 124 has the same height 130, angle 131, and spacing or distance 132, or they are different. The top layer of mixing portion 120 may have any suitable thickness ranging between 0.01 mm and 10 mm.

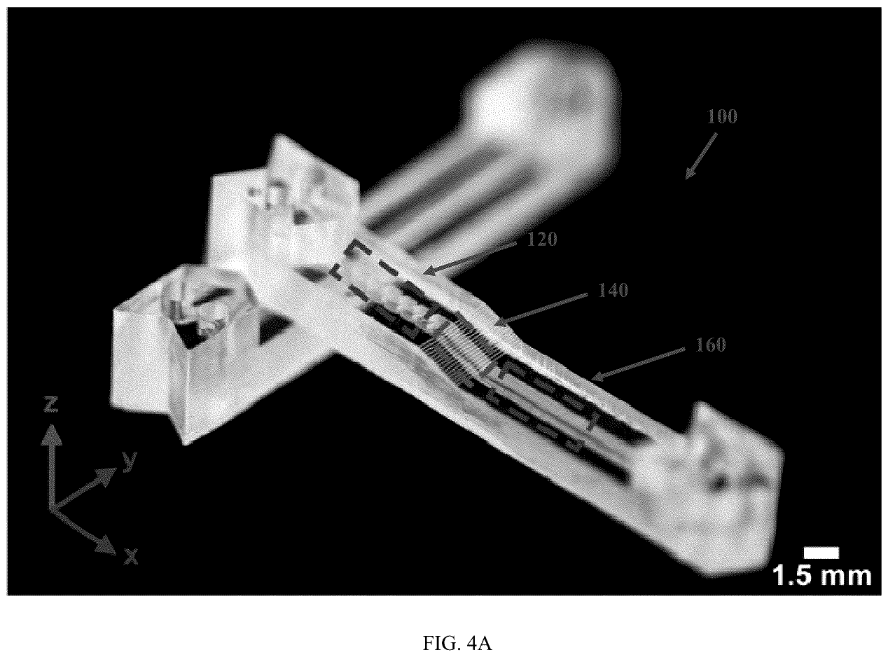

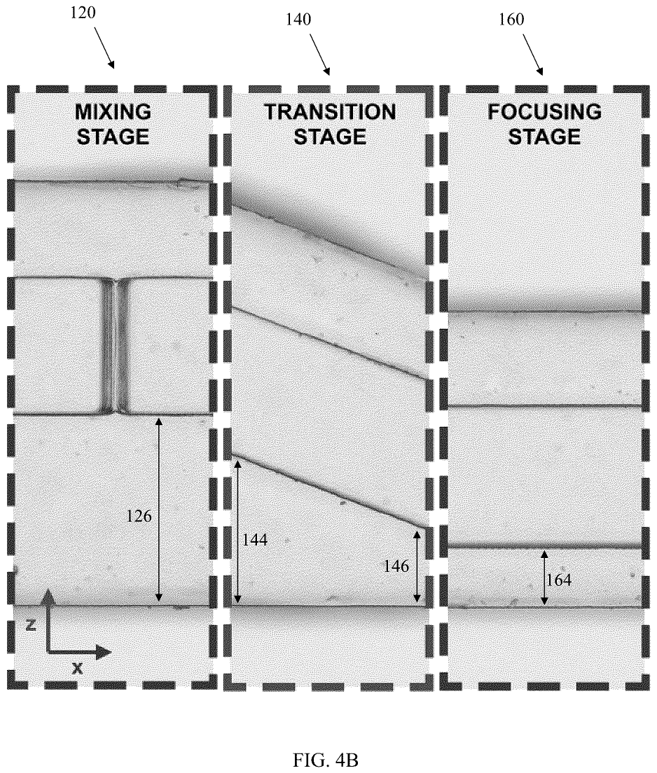

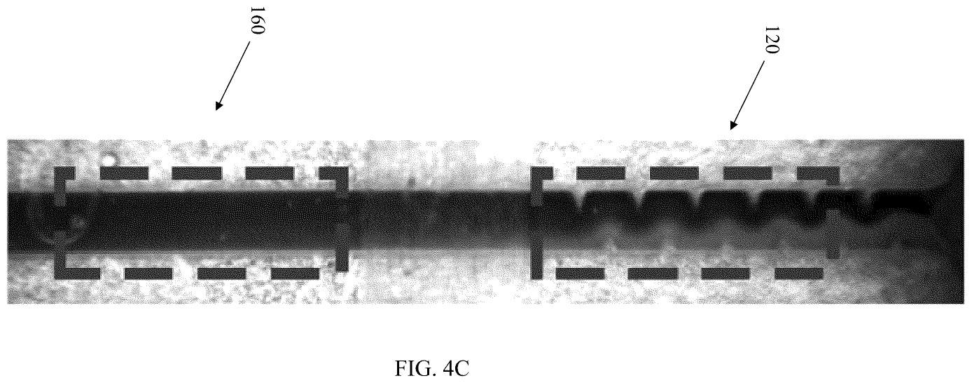

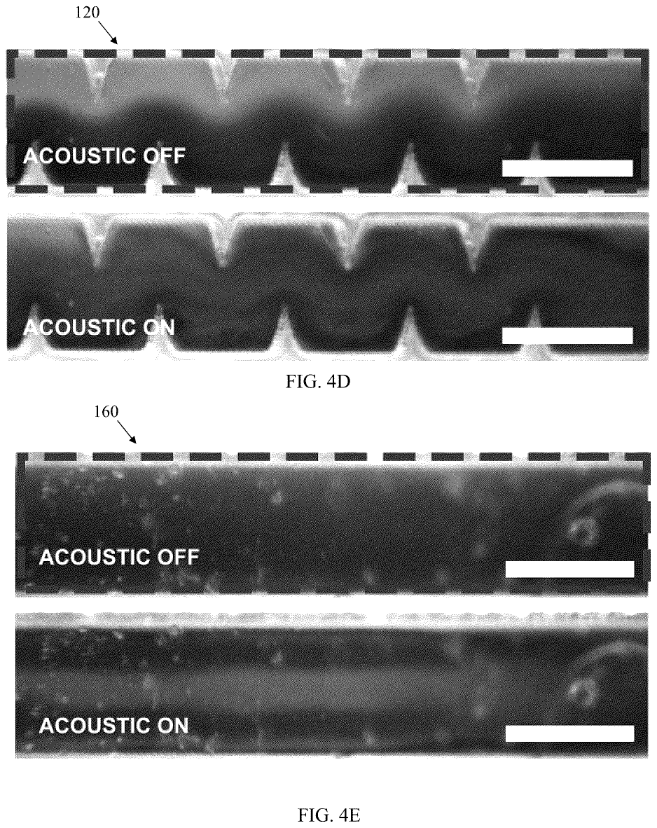

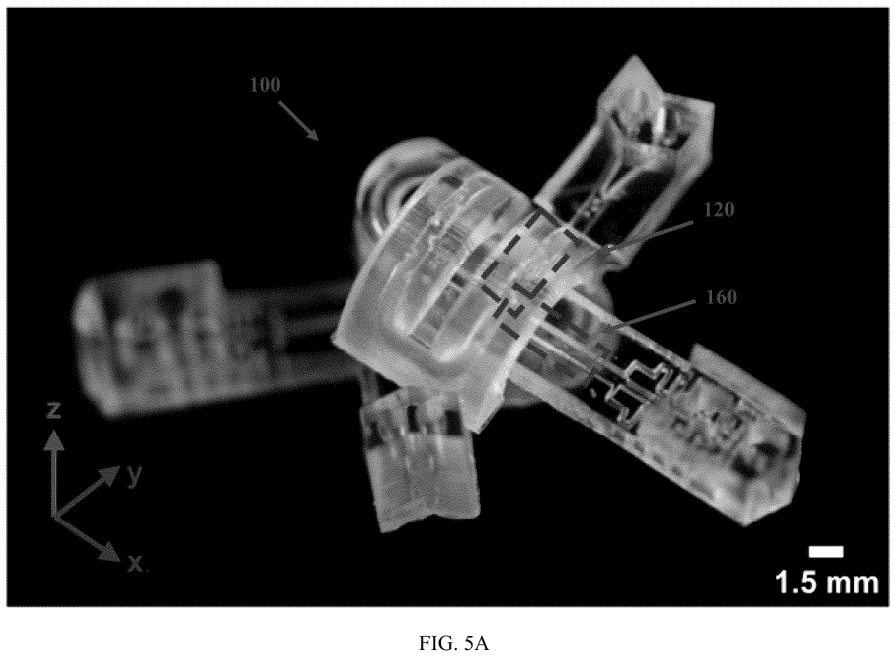

Aspects of the disclosure relate to the features, dimensions and geometries for transition portion 140. Referring now to FIG. 1A and FIG. 4B, shown are features and dimension lines for exemplary transition portion 140. In some embodiments, the base or bottom layer 141 of transition portion 140 has a taper or ramp comprising one or more thicknesses. For example, in some embodiments, the bottom layer 141 comprises a first thickness 144 and a second thickness 146. In some embodiments, first thickness 144 is greater than second thickness 146. In some embodiments, first thickness 144 ranges between 0.01 mm and 50 mm, and second thickness 146 ranges between 0.01 mm and 50 mm. In some embodiments, transition channel 142 comprises at least one width ranging between 0.01 mm and 10 mm. In some embodiments, transition channel 142 comprises at least one height ranging between 0.01 mm and 10 mm. As discussed above, transition channel 142 may have any number of curves or bends, each ranging between 15° and 270°. In some embodiments, channel 142 has an overall length ranging between 1 mm and 100 mm. The top layer of transition portion 140 may have any suitable thickness ranging between 0.01 mm and 10 mm.

Aspects of the disclosure relate to the features, dimensions and geometries for focusing portion 160. FIG. 1C is an image of an exemplary acoustic focusing stage or portion 160 according to aspects of the present disclosure. In some embodiments, the focusing channel 162 comprises a geometry transition along the length of the channel. For example, in some embodiments, the focusing channel 162 comprises a square cross-section that transitions to circular cross-sections at either ends of the channel. In some embodiments, the transition between the differently shaped cross-sections is gradual, or comprises a tapering portion or reducing neck.

Referring now in particular to FIGS. 1D-1F, shown are front, side and top cross-sectional views of an exemplary acoustic focusing stage or portion 160 with dimension lines. In some embodiments, channel 162 has a height 172 ranging between 0.01 mm and 10 mm, and a width 174 ranging between 0.01 mm and 10 mm. In some embodiments, height 172 is about 500 μm and width 174 is about 750 μm. In some embodiments, channel 162 has an overall length ranging between 1 mm and 100 mm. In some embodiments, bottom layer 161 has a thickness 164 ranging between 0.01 mm and 50 mm. In some embodiments, thickness 164 is about 400 μm. In some embodiments, top layer 165 has a thickness 166 ranging between 0.01 mm and 50 mm. In some embodiments, thickness 166 is about 600 μm. In some embodiments, thickness 166 is greater than thickness 164. In some embodiments, thickness 166 has a ratio to thickness 164 of 1:1, 1.1:1, 1.2:1, 1.3:1, 1.4:1, 1.5:1, 1.6:1, 1.7:1, 1.8:1, 1.9:1, 2.0:1, 2.1:1, 2.2:1, 2.3:1, 2.4:1, 2.5:1, 2.6:1, 2.7:1, 2.8:1, 2.9:1, 3.0:1, 3.1:1, 3.2:1, 3.3:1, 3.4:1, 3.5:1, 3.6:1, 3.7:1, 3.8:1, 3.9:1, 4.0:1, 4.1:1, 4.2:1, 4.3:1, 4.4:1, 4.5:1, 4.6:1, 4.7:1, 4.8:1, 4.9:1, 5.0:1. In some embodiments, sidewall 163a has a width 170a ranging between 0.1 mm and 10 mm. In some embodiments, sidewall 163b has a width 170b ranging between 0.1 mm and 10 mm. In some embodiments, width 170a and/or width 170b is about 1.5 mm. In some embodiments, width 170a and 170b are the same, or different.

Referring again to FIG. 1I, dimension lines for an exemplary outlet portion 180 are shown, and exemplary dimensions are described herein. In some embodiments, first channel 184a has an overall length ranging between 0.001 mm and 100 mm, a width 187a ranging between 0.001 mm and 5 mm, and a height ranging between 0.001 mm and 5 mm. In some embodiments, second channel 184b has an overall length ranging between 0.001 mm and 100 mm, a width 187b ranging between 0.001 mm and 5 mm, and a height ranging between 0.001 mm and 5 mm. In some embodiments, third channel 184c has an overall length ranging between 0.001 mm and 100 mm, a width 187c ranging between 0.001 mm and 5 mm, and a height ranging between 0.001 mm and 5 mm. In some embodiments, first cavity 185a has a length, width and/or height ranging between 0.001 mm and 20 mm. In some embodiments, second cavity 185b has a length, width and/or height ranging between 0.001 mm and 20 mm. In some embodiments, one or more outlets 114 (e.g., first outlet 114a, second outlet 114b) each have a width or diameter ranging between 0.001 mm and 20 mm.

Any of the channels, conduits, and/or fluid pathways of device 100 can be formed or profiled in one or more shapes. For example, any of the channels may comprise a geometry transition and comprise two or more shapes or profiles, such as shown in FIG. 1C and described above, or may be formed in a single shape or profile. The channels, conduits and/or fluid pathways may be formed in circular, round, oval, oblong, elliptical, square, rectangular, trapezoid, triangular, polygon, pentagon, hexagon, heptagon, octagon, or irregular shapes, and/or any combinations thereof.

Device 100 is optimized for fluid, particle, material, cell, and/or organoid mixing in mixing portion 120, transitioning of the mixture through transition portion 140, and focusing of material, particles, cells, and/or organoids in focusing portion 160. This is achieved, in part, via different thicknesses for bottom layer 121 of mixing portion, bottom layer 141 of transition portion 140, and bottom layer 161 of focusing portion 160. In some embodiments, thickness 126 of bottom layer 121 is greater than thickness 164 of bottom layer 161. As discussed further herein, the specific dimensions and material(s) for focusing portion 160 allow focusing of material, particles, cells, and/or organoids centrally in focusing channel 162 along axis 167 by creating reflection conditions which enables a resonance within the channel. The thicker bottom layer 121 of mixing portion 120 does not create the same reflective, resonance conditions, and therefore the mixing occurs without focusing. The bottom layer 141 of transition portion 140 comprises a gradual slope from the thickness 126 of bottom layer 121 to the thickness 164 of bottom layer 161, providing a pathway for fluid to flow between channels 122 and 162. Device 100 is optimized to function with a single transducer operating at a single frequency and wavelength, as discussed further herein.

Device 100 may be manufactured using an additive manufacturing (AM) process. Among the most common forms of additive manufacturing are the various techniques that fall under the umbrella of “3D printing”, including but not limited to stereolithography (SLA), soft lithography, digital light processing (DLP), micro-digital light processing (μDLP), fused deposition modelling (FDM), selective laser sintering (SLS), selective laser melting (SLM), electronic beam melting (EBM), and laminated object manufacturing (LOM). These methods “build” a three-dimensional physical model of a part, one layer at a time, providing significant efficiencies in rapid prototyping and small-batch manufacturing. AM also makes possible the manufacture of parts with features that conventional subtractive manufacturing techniques (for example CNC milling) are unable to create. In some embodiments, an AM process may comprise building a three-dimensional physical model from a single material, while in other embodiments, a single AM process may be configured to build the three-dimensional physical model from more than one material at the same time. In some embodiments, an AM layer thickness ranges between 0.01 mm and 1 mm.

Device 100 may be formed as a single unit and/or manufactured as one monolithic structure. In some embodiments, all of inlet portion 110, mixing portion 120, transition portion 140, focusing portion 160 and outlet portion 180 may be formed as one continuous structure, for example, by one or more AM processes described above. Device 100 may be formed from any suitable materials, including, but not limited to, hard materials, rigid materials, inelastic materials, soft materials, elastic materials, metals, composites, plastics, polymers, resins, high-performance resins, biocompatible resins, polymer resins, photopolymer resins, resins comprising mixtures of acrylates, methacrylates, and epoxy resins, and any combinations thereof. In some embodiments, device 100 is formed of a monolithic structure (e.g., body 102) comprising a low-acoustic impedance polymer resin and/or a photopolymer resin fabricated via additive manufacturing. In some embodiments, device 100, and dimensions thereof, are recharacterized and/or re-dimensioned to retain appropriate acoustic qualities depending on the selected material.

In some embodiments, methods of making an acoustofluidic device as described herein include fabricating a microfluidic chip using an AM process to form a monolithic structure comprising one or more fluidic channels. In some embodiments, the method comprises defining a mixing portion, a transition portion, and a focusing portion within the microfluidic chip, and selectively controlling geometric parameters of each portion, including channel dimensions and surrounding material thicknesses. In some embodiments, the method comprises forming a mixing portion having a first bottom layer thickness and a focusing portion having a second bottom layer thickness different from the first bottom layer thickness, and optionally forming a transition portion having a gradually varying thickness between the first and second thicknesses. In some embodiments, the method comprises forming one or more protrusions within the mixing portion to promote acoustic streaming and fluid mixing, and selecting a width of the focusing portion based on an acoustic wavelength corresponding to an intended operating frequency. In some embodiments, the method comprises coupling a transducer to the microfluidic chip such that, upon application of acoustic excitation, the device is configured to produce mixing in the mixing portion and particle focusing in the focusing portion.

In some embodiments, a method of making an acoustofluidic device comprises fabricating a microfluidic chip with a micro digital light processing (μDLP) resin printer using a resin formulated for microfluidic applications and printing the chip in a layer-by-layer manner at a selected layer thickness. In some embodiments, the method comprises printing the chip as a monolithic structure defining one or more internal microfluidic channels comprising a mixing portion, an optional transition portion, and a focusing portion. In some embodiments, the method comprises, after printing, flushing the printed chip while on a build plate, removing the chip from the build plate, washing and sonicating the chip, flushing internal channel features with deionized water, ultraviolet curing the chip, drying the chip with air, and heat treating the chip to improve optical clarity.

Aspects of the disclosure relate to an integrated acoustic mixing and focusing platform or system 200. Referring to FIGS. 1J-1M, various depictions of system 200 are shown. Referring now to FIG. 1J in particular, an exemplary system 200 is shown comprising at least one microfluidic device 100 positioned on top of a transducer 205, which is positioned on top of a cooling block 210. The system 200 functions by applying an acoustic signal to device 100, while the cooling block 210 cools the transducer 205 and device 100. Device 100, transducer 205 and/or cooling block 210 may be affixed to one another, permanently or removably, via any suitable means, such as, but not limited to, glues, adhesives, double-sided tape, and the like.

System 200 may comprise any number of connectors, tubes, fluid reservoirs and fluid management systems (e.g., syringes, pumps) connected to, and controlled by, portions of the device. For example, 4 separate tubes may connect to inlets 108a, 108b and outlets 114a, 114b. One or more syringes or pumps may be used to push fluid through the inlets and channels of device 100. One or more sensors, traps, or sinks may be used to measure and/or collect fluid, particles, materials, cells, organoids, etc., out of the outlets of device 100. The system 200 is configured to operate at fluid flow rates between 1 μL/min and 1000 L/min. In some embodiments, system 200 is configured to operate at fluid flow rates of about 32 μL/min. The system 200 may operate with any suitable fluids, including but not limited to, oil, silicone oil, water, salt water, and the like. The cooling block 210 is configured to maintain a temperature for system 200 with minimal drift, the temperature ranging between 10 °C and 40 °C, or between about 14 °C and 17 °C.

Referring now to FIG. 1K, an exemplary system 200 is shown wherein the transducer 205 is electrically connected to various components for powering, operating and measuring the transducer. In some embodiments, system 200 comprises a function generator 220 and power source 230 connected to an amplifier 240, wherein the amplifier 240 is connected to transducer 205. In some embodiments, an oscilloscope is connected between the amplifier 240 and transducer 205 to sample or measure the signal being generated to the transducer 205. Transducer 205 may be any suitable acoustic transducer or actuator, such as a piezoelectric element or transducer, configured to output any frequency ranging between 0.1 MHz and 100 MHz, at a peak-to-peak voltage (Vpp) ranging between 1 Vpp and 100 Vpp. Transducer 205 can be any suitable size and shape. For example, transducer 205 can be rectangular, square, round, oblong, ovular, or irregular shape. Transducer 200 can have any suitable dimensions with each of a height, width and length ranging between 0.1 mm and 100 mm. System 200 may comprise any number of sensors configured to measure or sense any aspects of the system. For example, system 200 may comprise sensors positioned within or contacting device 100, transducer 205, cooling block 210, and any other components of the system. In some embodiments, device 100 comprises one or more sensors positioned inside or fluidly contacting any of the channels or conduits, such as flow sensors, temperature sensors, vibration sensors, impedance sensors, optical sensors, cytometry sensors, biosensors, biosignal sensors, and the like. System 200 may operatively and electronically connect to computer 1100 disclosed further herein, and utilize any of sensors 1165.

When power and/or a signal is applied to transducer 205, acoustic energy is applied to device 100. This causes the fluid, material, particles, cells and/or organoids within the various channels of the device to receive the acoustic energy, causing mixing and focusing within mixing portion 120 and focusing portion 160, respectively. Referring back to FIGS. 1G and 1H, diagrams are shown wherein the acoustic energy imparted via the transducer 205 is powered on and off. FIG. 1G is a schematic of fluid and particle distribution in the mixing portion 120, and FIG. 1H is a schematic of fluid and particle distribution in the focusing portion 160.

Aspects of the disclosure relate to a method of using system 200. In some embodiments, the method comprises the steps of: directing a first fluid comprising one or more of a first material, particle, cell, and/or organoid into a first inlet (e.g., inlet 108a) of device 100; directing a second fluid comprising one or more of a second material, particle, cell, and/or organoid into a second inlet (e.g., inlet 108b) of device 100; conveying the first and second fluids into the mixing channel 122 of device 100; applying an acoustic excitation to the microfluidic device via a transducer (e.g., transducer 205) to induce acoustic streaming within the mixing channel 122 to mix the first and second fluids; conveying the mixed fluid into the focusing channel 162 of device 100; establishing a standing acoustic wave within the focusing channel 162 to spatially organize, concentrate, or separate one or more of the materials, particles, cells, and/or organoids; and directing the mixed and/or spatially organized, concentrated, or separated materials, particles, cells, and/or organoids to the outlet portion 180 of device 100 and out of the one or more outlets 114.

In some embodiments, the method comprises directing a first portion of the fluid to a first outlet (e.g., outlet 114a) and retrieving or collecting one or more of mixed and/or focused materials, particles, cells, and/or organoids from the first outlet; and directing a second portion of the fluid to a second outlet (e.g., outlet 114b) and removing or discarding waste therefrom.

In some embodiments, the method comprises controlling one or more acoustic parameters of the transducer (e.g., transducer 205) to achieve desired mixing and focusing behavior within the device 100. For example, a frequency of the acoustic excitation may be selected based on a wavelength corresponding to one or more dimensions of the focusing channel (e.g., focusing channel 162) to establish a standing acoustic wave therein. An amplitude of the acoustic excitation may be adjusted to control an intensity of acoustic streaming within the mixing channel (e.g., mixing channel 122) and/or a strength of particle focusing within the focusing channel. In some embodiments, the acoustic excitation is tuned to maintain a desired resonance condition within the microfluidic device.

In some embodiments, the method further comprises controlling a temperature of the microfluidic device 100 and/or the transducer 205 using a cooling element (e.g., a cooling block 210) in thermal communication therewith. Temperature control may be used to reduce or prevent drift in acoustic properties, including changes in acoustic wavelength, resonance conditions, or fluid properties during operation. In some embodiments, maintaining a substantially stable temperature improves consistency of mixing and focusing performance over time and enables sustained operation under continuous-flow conditions.

Another exemplary method of using system 200 is described. FIG. 1L is an image of an exemplary integrated acoustic mixing and focusing system 200 configured for an enzyme-linked affinity assay according to aspects of the present disclosure. HRP is Horseradish Peroxidase, MB is magnetic bead, and STRP is streptavidin. Biotin-HRP in a fluid medium is added to first inlet 108a, and MB-STRP in a fluid medium is added to inlet 108b. The fluid, materials and particles are directed to mixing portion 120, where they are mixed, and then further directed to focusing portion 160, where MB-STRP and Biotin-HRP are focused into a central portion of channel 162. FIG. 1M is an image of an exemplary integrated acoustic mixing and focusing system 200 under UV light produced by one or more light sources 260.

The disclosed technology has several advantages. The microfluidic device 100 enables complex, truly three-dimensional microfluidic architectures in a monolithic device form factor. System 200 overcomes challenges associated with low-acoustic-impedance polymer resins and establishes design rules based on precise control over channel and surrounding material dimensions (e.g., wall thicknesses) to achieve robust acoustofluidic functions including efficient sharp-edge-based mixing and effective particle focusing using a bulk acoustic wave resonance mode. By leveraging the design freedom provided by AM, an integrated, monolithic device driven by a single piezoelectric element (e.g., transducer 205) that sequentially performs acoustic mixing and focusing within spatially distinct regions enabled by engineered variations in the 3D channel structure. This disclosure establishes μDLP AM as a key enabler for next generation acoustofluidic platforms by demonstrating how true 3D architectural control over channel geometry can yield integrated, multifunctional polymer acoustofluidic devices with an expanded functional design space.

System 200 combines micromixing and particle focusing functionalities in a single, integrated device. By drawing upon design principles from established sharp-edge micromixers fabricated via soft lithography, an acoustically driven micromixer is disclosed with well-defined sharp-edge features and robust performance in efficiently mixing fluids across a range of flow conditions. In some embodiments, system 200 comprises a complementary particle-focusing portion 160 to illustrate the broad applicability of 3D-printed systems in manipulating suspended matter. In some embodiments, system 200 comprises a multi-layer design that is united to highlight how 3D printing enables complex, multifunctional geometries that were previously challenging or impossible to realize using conventional microfabrication strategies. Collectively, these findings establish a blueprint for leveraging emerging AM approaches to expand the design space, streamline fabrication, and enhance the functionality of next-generation acoustofluidic devices.

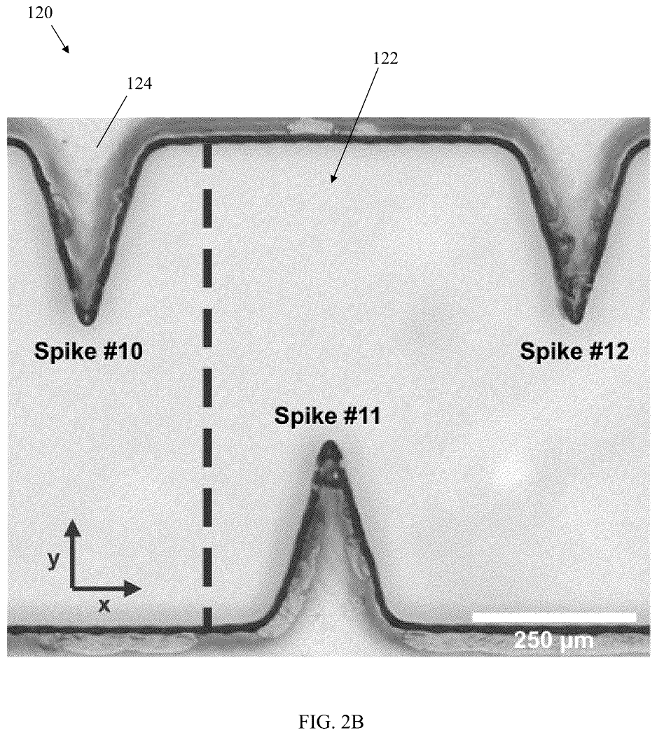

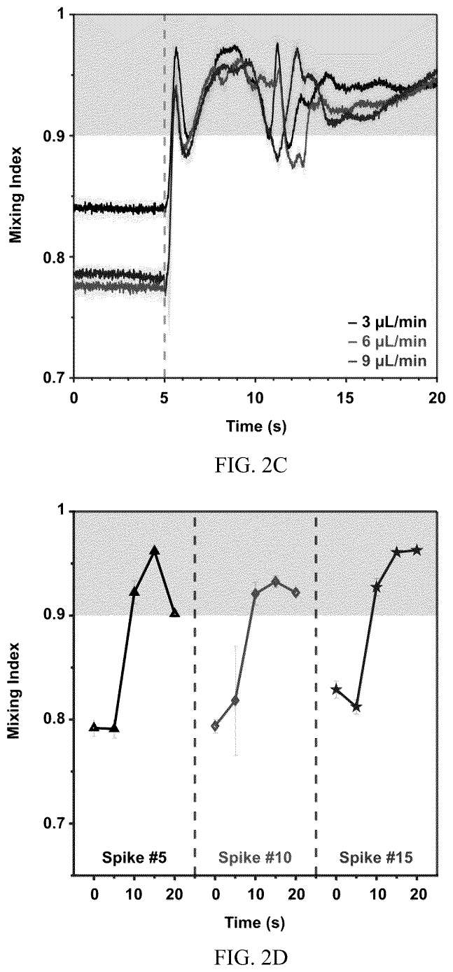

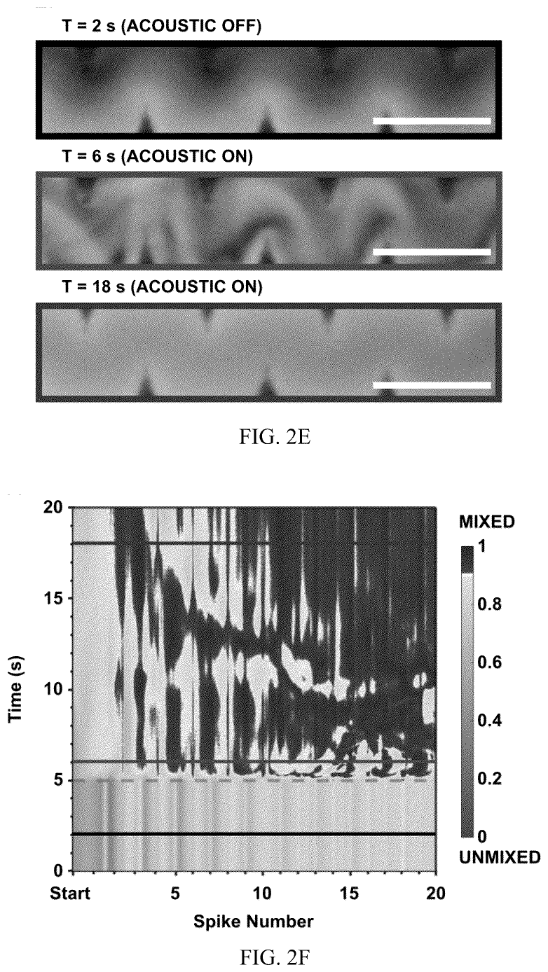

System 200 incorporates a series of sharp-edge spike features (plurality of spikes 124, FIG. 2B) to promote rapid fluid mixing. The sharp-edge spike features in system 200, along with the acoustic excitation from transducer 205 (e.g., piezoelectric actuator) induce tip vibrations that generate strong acoustic streaming with two counter-rotating vortices at each spike tip. This approach enhances mixing efficiency through modifications to the spike geometry, as decreasing the tip angle 131 can enhance mixing. Moreover, configuring sharp edges in a staggered pattern, rather than in directly opposing positions, provided additional improvements in mixing performance. In polymer acoustophoresis platforms such as system 200, the resonance phenomena occur across the entire device which results in all dimensional features (e.g., top and bottom walls, sidewalls, and channel cross-sections) holding the potential to critically influence acoustic wave propagation and resonance conditions.

As demonstrated in the Experimental Examples section below, acoustic focusing performance is strongly dependent on the relative thicknesses of the device layers, particularly the top and bottom layer dimensions of focusing portion 160, which govern acoustic wave reflection conditions in low-acoustic-impedance polymer materials. Specifically, optimization of these thicknesses (e.g., in disclosed ratios such as a 600 μm top thickness and 400 μm bottom thickness) enables formation of a stable pressure node within channel 162, thereby achieving reliable particle focusing. These results establish that precise tuning of layer thickness ratios directly influences resonance behavior and is critical to overcoming reduced acoustic reflectivity in polymer-based acoustofluidic systems.

The Experimental Examples section below further demonstrates that the width 174 of focusing channel 162 is directly related to the acoustic wavelength and operating frequency required to establish a standing wave for particle focusing. In particular, a half-wavelength resonance condition (Eqns. 3 & 4) is employed, where the selected operating frequency (e.g., 1 MHz) and the speed of sound in the medium (e.g., the fluid) determine the wavelength, and thus the appropriate channel width. For example, using a known speed of sound in silicone oil, a channel width 174 of approximately 500 μm is selected to support formation of a single pressure node, thereby enabling controlled particle focusing within channel 162.

The Experimental Examples section below also highlights that the low acoustic impedance of polymeric materials used in 3D-printed devices reduces inherent acoustic wave reflection, which can hinder formation of stable standing wave conditions. As a result, device performance is highly dependent on compensating for this reduced reflection through structural design, including adjustment of channel dimensions and surrounding material thicknesses. By engineering these parameters, sufficient acoustic wave reflection can be achieved to support resonance and particle focusing, demonstrating that reflection efficiency in such systems is governed by the interaction between material properties and device geometry.

In some embodiments, the acoustofluidic devices and systems described herein may be configured for use in a variety of analytical and biochemical applications. For example, the integrated mixing and focusing functionalities may be utilized to facilitate biochemical assays in which reagents introduced through one or more inlets are acoustically mixed to promote interaction, binding, or reaction between particles, molecules, cells, and/or organoids within a fluid medium. Following mixing, the focusing portion of the device may be configured to concentrate, align, or otherwise spatially organize selected particles or reaction products within the fluid stream, enabling downstream detection, analysis, or collection. In some embodiments, such configurations may be used in affinity-based assays, enzymatic reactions, or particle-based binding assays, wherein controlled mixing enhances reaction kinetics and acoustic focusing enables improved signal detection or separation of bound and unbound species. The integration of these functions within a single device may reduce system complexity while enabling continuous-flow processing of samples. In some embodiments, the disclosed acoustofluidic devices and systems can be used for biomanufacturing of various organic components (fuels, etc.), pharmaceuticals, chemical compounds, etc.

Aspects of system 200 may electronically and communicatively connect to a computing device, such as computer 1100 disclosed herein. Accordingly, in some aspects of the present invention, software executing the instructions provided herein may be stored on a non-transitory computer-readable medium, wherein the software performs some or all of the steps of the present invention when executed on a processor.

Aspects of the invention relate to algorithms executed in computer software. Though certain embodiments may be described as written in particular programming languages, or executed on particular operating systems or computing platforms, it is understood that the system and method of the present invention is not limited to any particular computing language, platform, or combination thereof. Software executing the algorithms described herein may be written in any programming language known in the art, compiled, or interpreted, including but not limited to C, C++, C#, Objective-C, Java, JavaScript, MATLAB, Python, PHP, Perl, Ruby, or Visual Basic. It is further understood that elements of the present invention may be executed on any acceptable computing platform, including but not limited to a server, a cloud instance, a workstation, a thin client, a mobile device, an embedded microcontroller, a television, or any other suitable computing device known in the art.

Parts of this invention are described as software running on a computing device. Though software described herein may be disclosed as operating on one particular computing device (e.g. a dedicated server or a workstation), it is understood in the art that software is intrinsically portable and that most software running on a dedicated server may also be run, for the purposes of the present invention, on any of a wide range of devices including desktop or mobile devices, laptops, tablets, smartphones, watches, wearable electronics or other wireless digital/cellular phones, televisions, cloud instances, embedded microcontrollers, thin client devices, or any other suitable computing device known in the art.

Similarly, parts of this invention are described as communicating over a variety of wireless or wired computer networks. For the purposes of this invention, the words “network”, “networked”, and “networking” are understood to encompass wired Ethernet, fiber optic connections, wireless connections including any of the various 802.11 standards, cellular WAN infrastructures such as 3G, 4G/LTE, or 5G networks, Bluetooth®, Bluetooth® Low Energy (BLE) or Zigbee® communication links, or any other method by which one electronic device is capable of communicating with another. In some embodiments, elements of the networked portion of the invention may be implemented over a Virtual Private Network (VPN).

FIG. 1N and the following discussion are intended to provide a brief, general description of a suitable computing environment in which the invention may be implemented. While the invention is described above in the general context of program modules that execute in conjunction with an application program that runs on an operating system on a computer, those skilled in the art will recognize that the invention may also be implemented in combination with other program modules.

Generally, program modules include routines, programs, components, data structures, and other types of structures that perform particular tasks or implement particular abstract data types. Moreover, those skilled in the art will appreciate that the invention may be practiced with other computer system configurations, including hand-held devices, multiprocessor systems, microprocessor-based or programmable consumer electronics, minicomputers, mainframe computers, and the like. The invention may also be practiced in distributed computing environments where tasks are performed by remote processing devices that are linked through a communications network. In a distributed computing environment, program modules may be located in both local and remote memory storage devices.

FIG. 1N depicts an illustrative computer architecture for a computer 1100 for practicing the various embodiments of the invention. The computer architecture shown in FIG. 1N illustrates a conventional personal computer, including a central processing unit 1150 (“CPU”), a system memory 1105, including a random access memory 1110 (“RAM”) and a read-only memory (“ROM”) 1115, and a system bus 1135 that couples the system memory 1105 to the CPU 1150. A basic input/output system containing the basic routines that help to transfer information between elements within the computer, such as during startup, is stored in the ROM 1115. The computer 1100 further includes a storage device 1120 for storing an operating system 1125, application/program 1130, and data.

The storage device 1120 is connected to the CPU 1150 through a storage controller (not shown) connected to the bus 1135. The storage device 1120 and its associated computer-readable media provide non-volatile storage for the computer 1100. Although the description of computer-readable media contained herein refers to a storage device, such as a hard disk or CD-ROM drive, it should be appreciated by those skilled in the art that computer-readable media can be any available media that can be accessed by the computer 1100.

By way of example, and not to be limiting, computer-readable media may comprise computer storage media. Computer storage media includes volatile and non-volatile, removable and non-removable media implemented in any method or technology for storage of information such as computer-readable instructions, data structures, program modules or other data. Computer storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other medium which can be used to store the desired information and which can be accessed by the computer.

According to various embodiments of the invention, the computer 1100 may operate in a networked environment using logical connections to remote computers through a network 1140, such as TCP/IP network such as the Internet or an intranet. The computer 1100 may connect to the network 1140 through a network interface unit 1145 connected to the bus 1135. It should be appreciated that the network interface unit 1145 may also be utilized to connect to other types of networks and remote computer systems.

The computer 1100 may also include an input/output controller 1155 for receiving and processing input from a number of input/output devices 1160, including a keyboard, a mouse, a touchscreen, a camera, a microphone, a controller, a joystick, or other type of input device. Similarly, the input/output controller 1155 may provide output to a display screen, a printer, a speaker, or other type of output device. The computer 1100 can connect to the input/output device 1160 via a wired connection including, but not limited to, fiber optic, Ethernet, or copper wire or wireless means including, but not limited to, Wi-Fi, Bluetooth, Near-Field Communication (NFC), infrared, or other suitable wired or wireless connections.

As mentioned briefly above, a number of program modules and data files may be stored in the storage device 1120 and/or RAM 1110 of the computer 1100, including an operating system 1125 suitable for controlling the operation of a networked computer. The storage device 1120 and RAM 1110 may also store one or more applications/programs 1130. In particular, the storage device 1120 and RAM 1110 may store an application/program 1130 for providing a variety of functionalities to a user. For instance, the application/program 1130 may comprise many types of programs such as a word processing application, a spreadsheet application, a desktop publishing application, a database application, a gaming application, internet browsing application, electronic mail application, messaging application, and the like. According to an embodiment of the present invention, the application/program 1130 comprises a multiple functionality software application for providing word processing functionality, slide presentation functionality, spreadsheet functionality, database functionality and the like.

The computer 1100 in some embodiments can include a variety of sensors 1165 for monitoring the environment surrounding and the environment internal to the computer 1100. These sensors 1165 can include a Global Positioning System (GPS) sensor, a photosensitive sensor, a gyroscope, a magnetometer, thermometer, a proximity sensor, an accelerometer, a microphone, biometric sensor, barometer, humidity sensor, radiation sensor, or any other suitable sensor.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore are not to be construed as limiting in any way the remainder of the disclosure.

3D Printing Monolithic, Multifunctional Polymer Acoustofluidic Devices with Tunable Mixing and Particle Focusing

Acoustic forces offer a powerful, contact-free modality for manipulating particles and fluids within microfluidic lab-on-a-chip systems. However, realizing the full potential of acoustic manipulation has been constrained by conventional cleanroom-based fabrication methods. Typically formed from high-acoustic-impedance materials like silicon or glass, these processes typically yield devices with limited design complexity owing to the planar channel geometries inherent in micromachining. Disclosed herein is a class of polymer-based acoustofluidic platforms fabricated using micro-digital light processing (μDLP) 3D printing. In contrast to micromachining, this additive manufacturing approach enables complex, truly three-dimensional (3D) microfluidic architectures in a monolithic device form factor. Herein, strategies are demonstrated to overcome challenges associated with low-acoustic-impedance polymer resins and establish design rules based on precise control over channel and surrounding material dimensions (e.g., wall thicknesses) to achieve robust acoustofluidic functions including efficient sharp-edge-based mixing and effective particle focusing using a bulk acoustic wave resonance mode. By leveraging the design freedom provided by additive manufacturing, an integrated, monolithic device was fabricated driven by a single piezoelectric element that sequentially performs acoustic mixing and focusing within spatially distinct regions enabled by engineered variations in the 3D channel structure. This example establishes μDLP additive manufacturing as a key enabler for next generation acoustofluidic platforms by demonstrating how true 3D architectural control over channel geometry can yield integrated, multifunctional polymer acoustofluidic devices with an expanded functional design space.

Controlled spatial manipulation of microscale constituents in fluid represents one of the key defining challenges in developing lab-on-chip technologies. Magnetic, electrokinetic, and optical approaches offer powerful strategies for achieving precision spatial control over targets of interest such as biological cells or magnetic beads; however, limitations resulting from throughput, biocompatibility, and fabrication considerations can hinder utility of such control strategies within a microfluidic lab-on-chip platform. In this context, acoustic forces represent an attractive alternative force handle and garner significant interest [S. Zhu et al., Analyst, 2020, 145, 7103-7124; Y. Yang et al., Small Methods, 2020, 4, 1900451; Y. Zhou et al., TrAC Trends in Analytical Chemistry, 2021, 145, 116452] as a means of achieving spatiotemporal control over both suspended matter (e.g., particles, cells, organoids) and complex fluid flows. Such acoustofluidic platforms [H. Bruus, Lab Chip, 2011, 11, 3742; M. Wu et al., Microsyst Nanoeng, 2019, 5, 32] are relatively material agnostic [R. R. Collino et al., Extreme Mechanics Letters, 2015, 5, 37-46; R. R. Collino et al., Materials Research Letters, 2018, 6, 191-198] as the interaction of acoustic forces depends upon intrinsic material properties rather than extrinsic labeling or material-specific parameters (e.g., magnetism). As acoustic forces can control matter across multiple length scales, recent examples highlight use in high-throughput cell sorting [M. Wu et al., Microsyst Nanoeng, 2019, 5, 32; Y. Chen et al., Lab Chip, 2016, 16, 3466-3472; J. Rufo et al., Nat Rev Methods Primers, 2022, 2, 30; T. Laurell et al., Chem. Soc. Rev., 2007, 36, 492-506], drug delivery [J. Park et al., Adv Healthcare Materials, 2021, 10, 2001096; H. Xiao et al., Journal of Controlled Release, 2024, 374, 205-218; J. Xu et al., Nat Commun, 2023, 14, 869], and the directed material assembly [R. R. Collino et al., Extreme Mechanics Letters, 2015, 5, 37-46; D. S. Melchert et al., Adv Materials Technologies, 2019, 4, 1900586; K. Johnson et al., MRS Advances, 2021, 6, 636-643; K. E. Johnson et al., Materials & Design, 2023, 234, 112328; S. Noparast et al., Adv Materials Technologies, 2024, 9, 2301950]. In aggregate, the unique advantages of acoustofluidic platforms offer powerful capabilities in a diverse array of applications spanning point-of-care diagnostics [M. Wu et al., Microsyst Nanoeng, 2019, 5, 32; M. P. Nair et al., Micromachines, 2021, 13, 24] to advanced manufacturing [R. R. Collino et al., Extreme Mechanics Letters, 2015, 5, 37-46; D. S. Melchert et al., Adv Materials Technologies, 2019, 4, 1900586; M.-S. Scholz et al., Ultrasonics, 2014, 54, 1015-1019; H. Yingbin, Mater. Horiz., 2021, 8, 885-911; S. Safaee et al., Additive Manufacturing, 2022, 51, 102642].

Acoustofluidic devices leverage both acoustic streaming and acoustic radiation forces to enable both solution mixing and particle positioning (FIGS. 1M, 1J, 1G & 1H). Acoustic streaming [M. Wiklund et al., Lab Chip, 2012, 12, 2438; S. S. Sadhal, Lab Chip, 2012, 12, 2292] drives bulk fluid motion to enhance mixing [N. Nama et al., Biomicrofluidics, 2016, 10, 024124; A. A. Doinikov et al., Microfluid Nanofluid, 2020, 24, 32; X. Zhao et al., Chemical Engineering Journal, 2022, 447, 137547; Z. Chen et al., Applied Materials Today, 2021, 25, 101239; P.-H. Huang et al., Lab Chip, 2013, 13, 3847] and is typically classified as either boundary layer streaming along solid surfaces, Eckart streaming in high-frequency regimes, or cavitation microstreaming from oscillating bubbles [M. Wiklund et al., Lab Chip, 2012, 12, 2438]. Sharp-edge oscillator [M. Wiklund et al., Lab Chip, 2012, 12, 2438; C. Zhang et al., Microfluid Nanofluid, 2019, 23, 104] microfluidics leverage boundary layer streaming to induce efficient mixing (FIG. 1G) and are thus the predominate design utilized in acoustofluidic micromixing devices.

In a complementary manner, acoustic radiation forces direct particle motion (acoustophoresis) through the acoustic contrast between the suspended particles and the surrounding fluid [R. R. Collino et al., Extreme Mechanics Letters, 2015, 5, 37-46; K. Johnson et al., MRS Advances, 2021, 6, 636-643; S. Safaee et al., Additive Manufacturing, 2022, 51, 102642]. Standing waves of pressure generated by piezoelectric actuators resonating the propagation medium drive particles either toward or away from pressure nodes as a consequence of the density and compressibility mismatches between the focusing target and surrounding media FIG. 1H. A one-dimensional model [T. Laurell et al., Chem. Soc. Rev., 2007, 36, 492-506; S. Liu et al., Sensors, 2017, 17, 1664; Z. Liu et al., The Journal of the Acoustical Society of America, 2016, 139, 332-349; S. M. Hagsäter et al., Lab Chip, 2008, 8, 1178] (Eqn. 1) describes the acoustic radiation force F_{rad} acting on particles.

$${F}_{r a d} = - \frac{π {P}_{1}^{2} {V}_{p} {β}_{f}}{2 λ} ϕ ( β , ρ ) sin ( 2 kx ) \qquad Equation 1$$

Here, P₁ is the applied acoustic pressure amplitude, Vₚ is the particle volume, β_{f} is the compressibility of the fluid, λ is the wavelength, φ(β,ρ) is the acoustic contrast factor, k is the wave number, and x is the particle position. By varying the applied peak-to-peak voltage, one can linearly increase the pressure amplitude P₁ to increase the strength of the applied acoustic force [T. Laurell et al., Chem. Soc. Rev., 2007, 36, 492-506; H. Bruus, Lab Chip, 2012, 12, 1014]. As the force scales with particle diameter, larger particles experience stronger focusing effects. [T. Laurell et al., Chem. Soc. Rev., 2007, 36, 492-506] The acoustic contrast factor (Eqn. 2), defined as the ratio of particle compressibility and density to the surrounding medium, determines the direction of particle movement.

FIG. 1M is an image of an exemplary experimental setup under UV light. FIG. 1J is a schematic illustration showing a resin 3D-printed chip adhered to a piezoelectric transducer, which is coupled to a cooling block to dissipate heat generated during acoustic application. FIG. 1G is a schematic of fluid and particle distribution on a mixing platform. FIG. 1H is a schematic of fluid and particle distribution on a focusing platform.

$$ϕ = \frac{5 {ρ}_{p} - 2 {ρ}_{f}}{2 {ρ}_{p} + {ρ}_{f}} - \frac{{β}_{p}}{{β}_{f}} \qquad Equation 2$$

Here, β_{f} is the compressibility of the surrounding fluid, βₚ is the compressibility of the particles, ρ_{f} is the density of the surrounding fluid medium, ρₚ is the density of the particles. Particles with a positive acoustic contrast factor (e.g., high density; low compressibility compared to surrounding medium) move towards the pressure node, while those with a negative contrast factor move towards the antinode [S. Liu et al., Sensors, 2017, 17, 1664; T. Laurell et al., Chem. Soc. Rev., 2007, 36, 492-506; A. Lenshof et al., Lab Chip, 2012, 12, 1210].

The two principal strategies for acoustic wave propagation in acoustofluidic devices are surface acoustic waves (SAW) and bulk acoustic waves (BAW). BAW systems commonly employ piezoelectric elements to establish standing waves of pressure in configurations comprising either pairs of piezoelectric elements or through a single element coupled with a high-impedance reflector. [M. Wu et al., Microsyst Nanoeng, 2019, 5, 32] Fabrication of conventional BAW-based acoustofluidic devices [I. Leibacher et al., Lab Chip, 2015, 15, 2896-2905; T. Laurell et al., Chem. Soc. Rev., 2007, 36, 492-506] requires use of cleanroom-based environments and capital-intensive processes (e.g., photolithography, deep-reactive silicon etching-DRIE) to form microfluidic channel geometries in silicon. [P. P. Austin Suthanthiraraj et al., Methods, 2012, 57, 259-271; C. W. Shields IV et al., JoVE, 2016, 53861] Alternative fabrication approaches seek to utilize mass-manufactured glass capillaries [A. Fornell et al., J. Phys. D: Appl. Phys., 2021, 54, 355401; B. Hammarström et al., Lab Chip, 2010, 10, 2251; G. Liu et al., Micromachines, 2021, 12, 876] or polymeric materials [F. Lickert et al., The Journal of the Acoustical Society of America, 2021, 149, 4281-4291; I. González et al., Sensors and Actuators B: Chemical, 2010, 144, 310-317]; however, such approaches introduce new limitations including restricted design geometries (i.e., glass capillaries) or reduced performance capabilities. For the approaches utilizing polymers such as polydimethylsiloxane (PDMS) and poly(methyl methacrylate) (PMMA) the lower acoustic impedance of the polymer materials results in a decreased efficacy for reflecting standing waves yielding resonance behavior that differs from platforms utilizing high-impedance materials [F. Lickert et al., The Journal of the Acoustical Society of America, 2021, 149, 4281-4291; X. Shu et al., Microfluid Nanofluid, 2018, 22, 32; Açikgöz H. N. et al., Ultrasonics, 2023, 129, 106911]. Thus, while these initial demonstrations highlight significant potential for polymeric acoustofluidic devices, the limited number of studies highlight the need to establish a new set of device design parameters to expand broad utilization.

Additive manufacturing, especially stereolithography (SLA) and digital light processing (DLP), holds immense promise for overcoming constraints encountered in traditional microfabrication of acoustofluidic devices or use of polymeric materials by enabling production of devices with true three-dimensional (3D) microfluidic architectures. Although current 3D-printing resolutions can lag behind those achievable in cleanroom processes, these techniques uniquely permit complex device geometries that are otherwise challenging or impossible to realize. [C.-H. Wu et al., Sci. Adv., 2023, 9, eadg4272; P. Azizian et al., Microsyst Nanoeng, 2023, 9, 91] Such geometries can support more effective acoustophoretic device performance [A. Tahmasebipour et al., The Journal of the Acoustical Society of America, 2020, 148, 359-373]. Recent demonstrations of 3D-printed acoustofluidic devices, for example, highlight early successes in particle separation, [A. Ozcelik, Actuators, 2022, 11, 249] yet many open questions remain regarding the interplay between material properties, channel geometries, and acoustic wave propagation in low-impedance resins.

In this example, disclosed is a new class of 3D-printed acoustofluidic platforms that combine micromixing and particle focusing functionalities in a single, integrated device. By drawing upon design principles from established sharp-edge micromixers fabricated via soft lithography, [X. Zhao et al., Chemical Engineering Journal, 2022, 447, 137547; Z. Chen et al., Applied Materials Today, 2021, 25, 101239] an acoustically driven micromixer was developed with well-defined sharp-edge features and its robust performance in efficiently mixing fluids across a range of flow conditions is demonstrated. Further disclosed is a complementary particle-focusing module, validated in two distinct media, to illustrate the broad applicability of these 3D-printed systems in manipulating suspended matter. Finally, in a multilayer design, these capabilities are united to highlight how 3D printing enables complex, multifunctional geometries that were previously challenging or impossible to realize using conventional microfabrication strategies. Collectively, these findings establish a blueprint for leveraging emerging additive manufacturing approaches to expand the design space, streamline fabrication, and enhance the functionality of next-generation acoustofluidic devices.

Device fabrication: A micro digital light processing (μDLP) resin printer (MiiCraft Profluidics 285D, Creative CADworks) fabricated all acoustofluidic devices from resin formulated for microfluidic applications (MiiCraft BV-007A, Creative CADworks) with a layer thickness of 50 μm. Subsequent removal of fabricated devices at the conclusion of the printing process facilitated a post-processing sequence. After a brief isopropyl alcohol (IPA) submersion (~10 s), flushing of internal printed features (e.g., channels) with deionized (DI) water, sonication in DI water for 4 min, drying by compressed air, UV-curing (5 min, CureZone, MiiCraft), and oven-based heat treatment (15 min, 70 °C) produced finished acoustofluidic devices.

Acoustophoretic Experiments: A custom-built experimental system comprising a function generator (SDG 2042X, SIGLENT), a power supply (1673, B&K Precision), an amplifier (LZY-22+, Mini Circuit), and a piezoelectric element (SMPL20W15T21R111, STEMiNC) generated prescribed acoustic fields within the 3D-printed acoustofluidic devices. Unless otherwise noted, experiments utilized a 1 MHz frequency at a peak-to-peak voltage (Vpp) of 45 Vpp to generate prescribed acoustic fields in the acoustofluidic devices.

3D-printed acoustofluidic devices were bonded onto piezoelectric transducers using adhesive (Super Glue Micro Precise Gel, Gorilla and 6-621-GEL, Dymax). Thermally conductive transfer tape (8810, 3M) then secured each chip-transducer unit to a cooling block, thereby minimizing temperature-related drift in the piezoelectric response. A USB camera (GS3-U3-51S5C-C, FLIR) interfaced with a stereo microscope (SPZ-50, Aven) provided real-time visualization. Control of the acoustic input parameters—frequency, voltage, and pulse duration—was implemented via a custom MATLAB-based graphical user interface.

For fluorescent imaging of micromixing, a UV light source (10 W Blacklight Strip Lights, Barrina) illuminated a 0.5 w/w % fluorescein sodium salt solution (46960, Sigma-Aldrich). A thin Kapton film (1 mil) placed over the objective lens blocked observation of a co-flowing, non-fluorescent, blue-dyed water (Soft Gel Paste, AmeriColor) by allowing transmission of only the fluorescence signal into the objective. In studies investigating acoustic focusing (alone) or the combined acoustic mixing/focusing configuration, both the UV illumination and Kapton filter were removed in favor of brightfield microscopy via the internal microscope illumination source. Prescribed microfluidic flow was provided via either a single-syringe pump (Pump 11 Elite Single Syringe, Harvard Apparatus) or a dual-syringe system (4002X, New Era) with selection depending on the requirements of each experiment.

Six distinct fluid mixtures were prepared for demonstration of acoustofluidic experiments. Unless otherwise noted, all aqueous solutions and electrolytes were prepared with deionized (DI) water Millipore (resistivity 18.25 MΩ cm⁻¹, Milli-Q, Millipore). (1) A 0.5 w/w % fluorescein sodium salt (46960, Sigma-Aldrich) solution; (2) A 0.6 w/w % visible blue dye (Soft Gel Paste, AmeriColor) tracer solution; (3) 2 w/w % black paramagnetic polyethylene microspheres (BKPMS-1.2, 38-45 μm, Cospheric) suspended in silicone oil (378380, Sigma-Aldrich), which was referred to as BPPM-SI; (4) 0.5 w/w % orange fluorescent polymer microspheres (FMO-1.3, 1-5 μm, Cospheric) suspended in (1) 0.5 w/w % fluorescein sodium salt solution (noted as OFPM-FSS); (5) 0.04 mg/mL streptavidin magnetic beads (MB-STRP) (Pierce™ Streptavidin Magnetic Beads, Thermo Scientific™); (6) 0.02 mg/mL biotinylated peroxidase (Biotin-HRP) (Invitrogen™). (5) and (6) were both prepared in 10 mM, pH 7.4 phosphate-buffered saline (PBS) (MP Biomedicals™) containing Tween-20 (Sigma-Aldrich) (PBS:Tween-20 volume ratio 100:0.05)

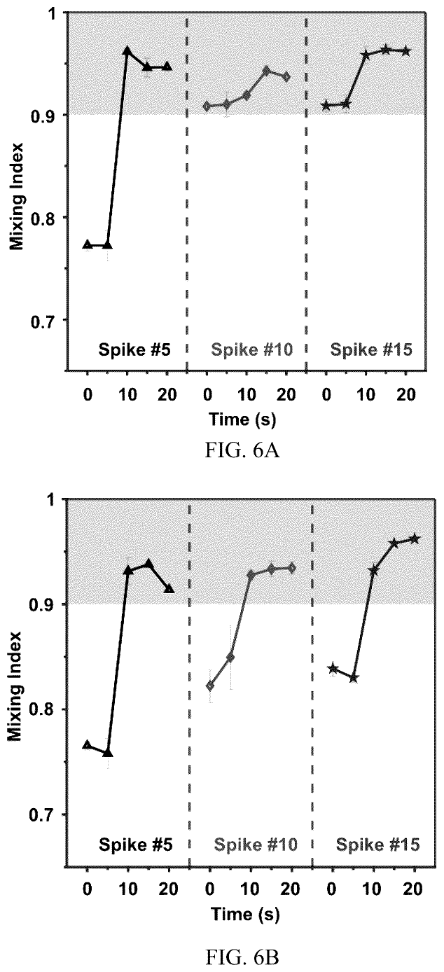

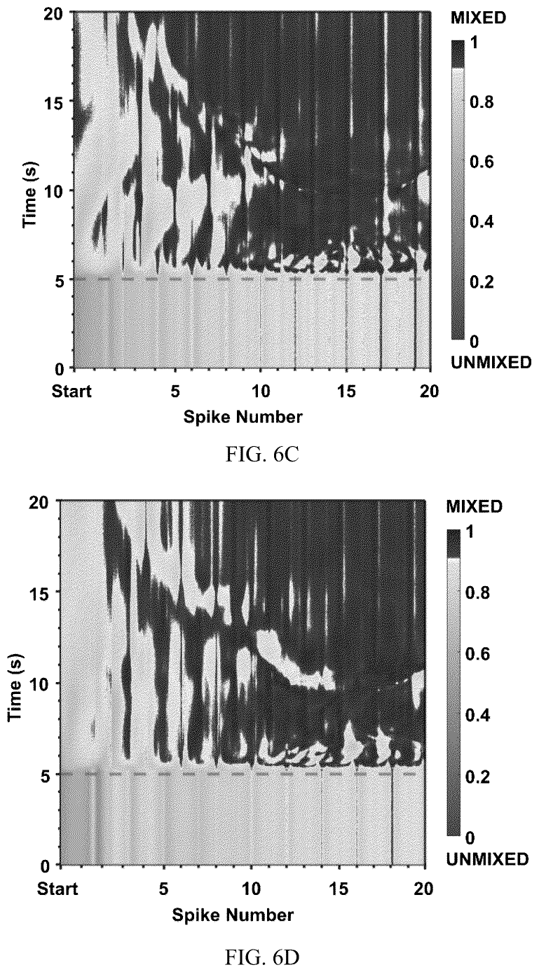

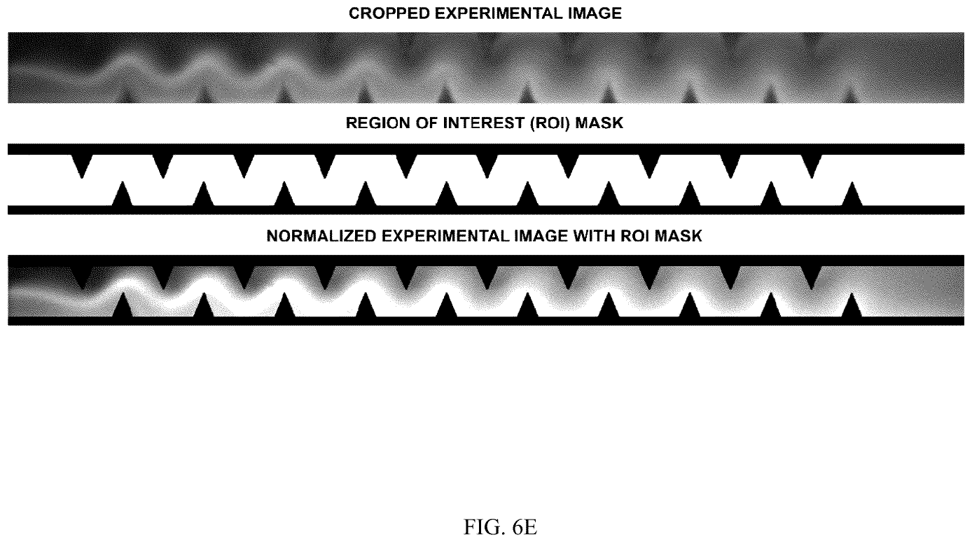

Calculation of Mixing Index: The mixing index (MI) [G. Cai et al., Micromachines, 2017, 8, 274; Z. Li et al., Sensors and Actuators A: Physical, 2022, 344, 113757] quantified mixing performance from 0 (unmixed) to 1 (fully mixed), with 0.9 as the threshold for acceptable mixing. A MATLAB script calculated MI from acquired images. Here, a mask of the channel inclusive of spike features overlaid on the image of interest covered the device top and bottom to exclude edge effects when evaluating pixel intensities (FIG. 6E). This masking isolated the channel's interior (no edge, no spike), ensuring only valid data is analyzed. MI was then calculated for each column along the device length across all acquired images throughout the experiment.

UV-Vis Analysis: 100 μL of the acquired mixture of MB-STRP and Biotin-HRP from the acoustic off and acoustic on conditions were washed three times with PBS using a DynaMag magnet (DynaMag™-2 Magnet, Invitrogen™). Subsequently, 150 μL of 3,3′,5,5′-tetramethylbenzidine (TMB) (1-Step™ TMB ELISA Substrate Solution, Thermo Scientific™) was added to the magnetically separated complex, resulting in the development of a blue color. Afterward, 200 μL of 2.5 M sulfuric acid (ACS reagent, 95.0-98.0%, Sigma-Aldrich) was added as a stop solution, causing the solution to turn yellow. The solution was decanted with the help of a DynaMag magnet and characterized using a UV-visible spectrometer (Ocean High-Resolution Spectrometer, Ocean Optics).

3D-Printed Acoustofluidics: Acoustic Mixing: A 3D-printed Y-channel micromixer (FIG. 2A) incorporated a series of sharp-edge spike features (FIG. 2B) to promote rapid fluid mixing. Sharp-edge spike features are commonly used in micromixer devices, [M. Wiklund et al., Lab Chip, 2012, 12, 2438; C. Zhang et al., Microfluid Nanofluid, 2019, 23, 104] where acoustic excitation from a piezoelectric actuator induces tip vibrations that generate strong acoustic streaming with two counter-rotating vortices at each spike tip. [N. Nama et al., Biomicrofluidics, 2016, 10, 024124] This approach leveraged a well-known capability to enhance mixing efficiency through modifications to the spike geometry, as decreasing the tip angle can enhance mixing. [P.-H. Huang et al., Lab Chip, 2013, 13, 3847; Z. Chen et al., Applied Materials Today, 2021, 25, 101239] Moreover, configuring sharp edges in a staggered pattern, rather than in directly opposing positions, provided additional improvements in mixing performance. [Z. Chen et al., Applied Materials Today, 2021, 25, 101239] In polymer acoustophoresis platforms the resonance phenomena occur across the entire device [M. B. Özer et al., J. Acoust. Soc. Am., 2021, 149, 2802-2812; F. Lickert et al., J. Acoust. Soc. Am., 2021, 149, 4281-4291] which results in all dimensional features (e.g., top and bottom walls, sidewalls, and channel cross-sections) holding the potential to critically influence acoustic wave propagation and resonance conditions. [F. Lickert et al., J. Acoust. Soc. Am., 2021, 149, 4281-4291]

FIG. 2A is an image of an exemplary resin 3D-printed micromixer featuring spikes within the channel. FIG. 2B is an image of an exemplary channel interior showing staggered spikes with numbering. The dark red dashed line indicates the analysis location at the midpoint between the spikes. FIG. 2C is a plot of mixing index (MI) at three flow rates (3, 6, and 9 μL/min) measured between spikes 10 and 11 (as shown in FIG. 2B). All three flow rates achieved the considered mixing threshold. FIG. 2D is a plot of MI at 9 μL/min across spike number during experimental acquisition. All spikes exceeded the considered mixing threshold when acoustic was enabled. FIG. 2E is representative microscopy images of an exemplary micromixer at different times. Scale bars represent 750 μm. FIG. 2F is a plot of MI at 9 μL/min in the region of interest over time. The magenta dashed line indicates the moment acoustic was enabled, while black, red, and blue solid lines represent images extracted in FIG. 2E. As the spike number increases, mixing improves.

This design utilized a nominal spike height of 350 μm, angle of 30°, and a staggered spacing of 750 μm, which yields 20 uniformly distributed spikes in total. Two visually distinct fluids—a blue tracer solution and a fluorescein solution-co-flowed at rates of 3, 6, or 9 μL/min to assess device mixing performance. The mixing index (MI) [G. Cai et al., Micromachines, 2017, 8, 274; Z. Li et al., Sensors and Actuators A: Physical, 2022, 344, 113757] value quantified the extent of mixing from the standard deviation of the pixel intensity (normalized) for a vertical range of pixels corresponding to the channel width. Values ranged from 0 (unmixed) to 1 (fully mixed), with 0.9 accepted [G. Cai et al., Micromachines, 2017, 8, 274; Z. Li et al., Sensors and Actuators A: Physical, 2022, 344, 113757] as the threshold for identifying a fully-mixed solution. The acoustofluidic channel designs ensured that purely diffusive mixing was insufficient to achieve MI≥0.9.

Calculation of MI at the midpoint between spikes 10 and 11 (FIG. 2C) enabled evaluation of the role of acoustics in promoting mixing. In the absence of acoustic excitation (initial 5 s), the MI followed the expected behavior that the degree of diffusive mixing is inversely proportional to flow rate (e.g., slower flow rates exhibit higher calculated MI values resulting from diffusion). Immediately upon application of the acoustic field (t=5 s) the value of MI increased in a stepwise fashion to initially surpass the 0.9 threshold before stabilizing under steady-state conditions. This resulted from the sharp-edge tips responding to the acoustic field to induce localized, accelerated channel mixing [A. A. Doinikov et al., Microfluid Nanofluid, 2020, 24, 32; C. Zhang et al., Chemical Engineering Journal, 2021, 410, 128252].

Examining MI at spike positions across the channel length (FIG. 2D; additional flow rates shown in FIGS. 6A and 6B) offered further insight into the interplay of diffusion and acoustic-driven mixing. In the absence of acoustic mixing, the MI value gradually increased with each progressive spike, reflecting cumulative diffusive mixing (as was expected). Immediately following the application of the acoustic field, the MI value increased abruptly and remained at or above 0.9. This performance underscored and confirmed the robust capacity for acoustophoretic forces to promote mixing in microfluidic channels. While the 20 spike design was sufficient for the selected flow rates, expanding the number of sharp edges and fabricating sharper tips may yield even higher mixing performance for systems demanding higher flow rates or shorter channel lengths. This is a key advantage of the demonstrated efficacy of the 3D-printed device platform disclosed herein, as the design cycle to generate a device from optimized channel geometries was rapid as compared to conventional glass/silicon acoustophoretic device platforms (ranged from hours to days).

Representative microscopy images (FIG. 2E) provided insight into the influence of diffusive mixing (no field applied, t=2 s), the flow behavior following the application of the acoustic field (t=6 s), and steady-state operation (t=18 s). In the absence of an applied acoustic field, the blue tracer and fluorescein solutions showed diffusive mixing. Visible perturbations appeared immediately following field application and by t=18 s a uniform steady-state condition is established across the channel length.

Examining the dynamic changes in MI values as a function of time and channel position (FIG. 2F) offered additional insight to the performance of acoustophoretic mixing in a 3D printed device. Before field application, the influence of diffusive mixing was evident in the gradual increase in MI values as a function of channel length (i.e., transition from dark to light purple). Upon field application (t=5 s) a sharp increase in MI values occurred across the channel length, which preceded the transitory period in which the flow and acoustic fields stabilized. The observed fluctuations in MI during this transient were noted as likely reflecting moment-to-moment variation in the local ratio of fluorescent to non-fluorescent fluid as the two streams interacted via acoustic mixing. The waterfall plot in FIG. 2F highlights that once the system reaches steady state the MI values consistently remained above 0.9, indicating robust and sustained mixing throughout the microfluidic channel.

3D-Printed Acoustofluidics: Acoustic Focusing: Demonstrations of acoustically mediated particle focusing in 3D-printed devices underscored the critical interplay between material properties and structural design. In low-acoustic-impedance materials, such as the polymeric resins utilized in vat photopolymerization 3D printing, single-transducer bulk acoustic wave (BAW) configurations can suffer from inadequate sound reflection, impeding the formation of a central pressure node [A. Lenshof et al., Lab Chip, 2012, 12, 684]. Strategic optimizations to the device geometry [F. Lickert et al., The Journal of the Acoustical Society of America, 2021, 149, 4281-4291], such as the top (tₜₒₚ) and bottom (t_{bottom}) dimensions (e.g., device thickness) can enable robust wave reflection and thus effective particle focusing.

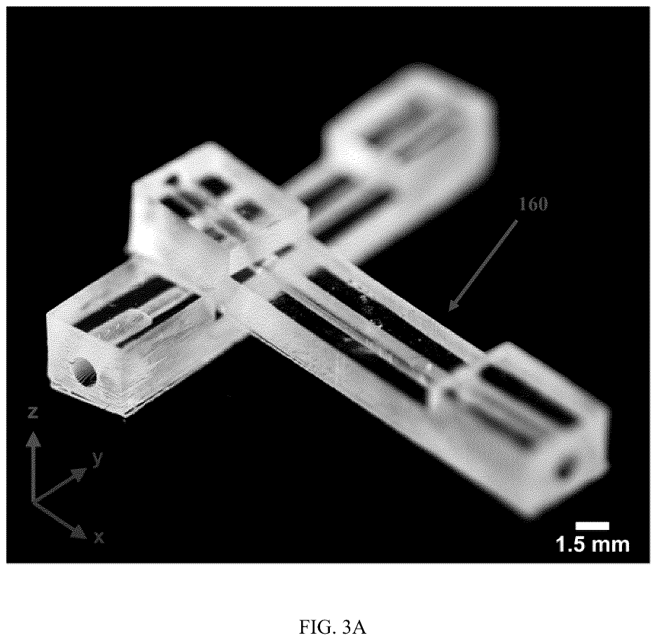

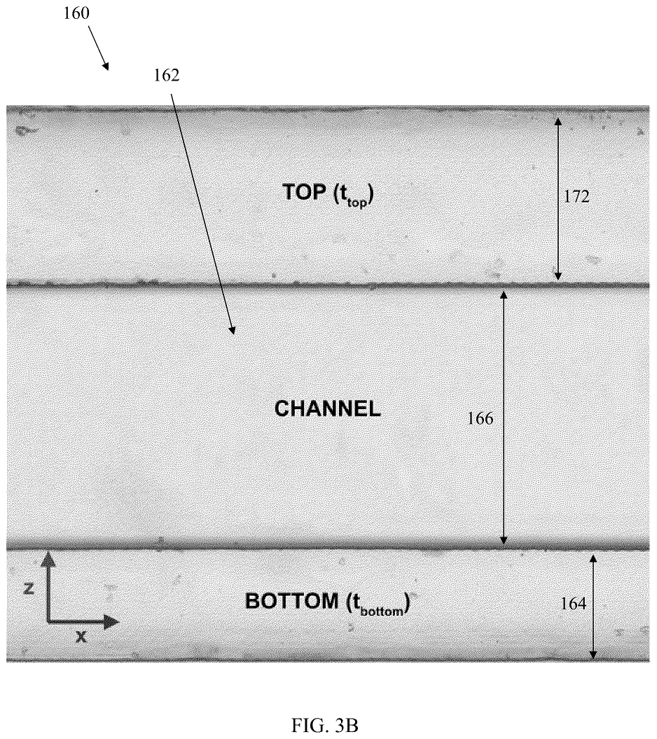

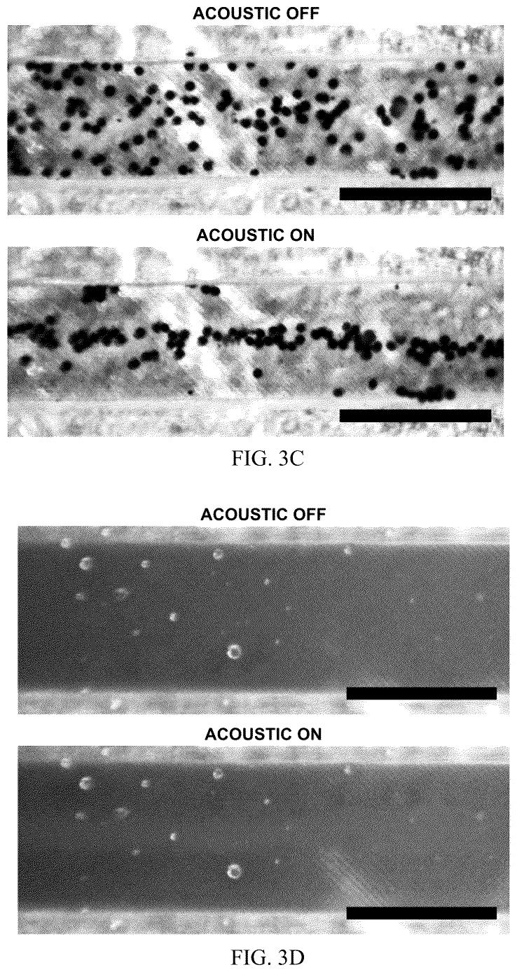

FIG. 3A is a photograph of a resin 3D-printed focusing device with a straight channel. FIG. 3B is a side-view schematic of the device, showing varying thicknesses of the bottom (tbottom) and top (ttop). FIG. 3C is an image showing black polyethylene microspheres suspended in silicone oil, imaged with acoustics off and on. Scale bars represent 750 μm. FIG. 3D is an image showing orange fluorescent polymer microspheres suspended in fluorescein salt solution, imaged with acoustics off and on. Scale bars represent 750 μm. In both cases, the microspheres aggregated at the channel center under acoustic conditions.

An acoustofluidic device (FIG. 3A) designed specifically for use at 1 MHz with a silicone oil-based medium (BPPM-SI) served as an initial proof-of-concept. Internal microfluidic channel dimensions followed calculations for the resonant conditions to establish a half-standing wave (i.e., one focusing node):

$$f = \frac{{v}_{w}}{λ} \qquad Equation 3$$

$$λ = 2 W \qquad Equation 4$$

where f is the frequency, v_{w} is the speed of sound in the medium, λ is the wavelength in that medium, and W is the device channel width. The system parameters (f=1 MHz, v_{w, silicone oil}=1040 m/s) resulted in a calculated channel width of 500 μm. A systematic investigation of the influence of tₜₒₚ and t_{bottom} dimensions (FIGS. 1C, 1D, 1E, 1F, 3B, 7E and 7F) on focusing performance established a 600 μm top channel thickness paired with a 400 μm bottom channel thickness and supported a wave reflection condition that enabled reliable particle focusing. This geometry optimization highlighted the critical role of external channel dimensions (e.g., material thicknesses) in achieving optimal performance in resin 3D-printed acoustic focusing devices.

These insights enabled fabrication of two prototype device designs: (i) a 500 μm internal square channel for the BPPM-SI system and (ii) a 750 μm internal square channel for a water-based medium containing fluorescent particles (OFPM-FSS). Both devices shared a uniform sidewall thickness of 1500 μm. Owing to the difference in the speed of sound for the two media (i.e., silicone oil, water), the internal channel dimensions of each device ensured formation of a half-standing wave at 1 MHz to focus particles to the center node of the channel.

In the initial demonstration system utilizing BPPM-SI (FIG. 3C), a random dispersion of microspheres existed in the absence of an applied acoustic field. An immediate migration of the microspheres into the central pressure node occurred upon the application of the acoustic field. A similar phenomenon occurred in OFPM-FSS (FIG. 3D) system. Although the size and concentration of the particles in solution was below the threshold of visual observation for the microscopy system utilized in this example, the application of the acoustic field focused the particles to the central pressure node resulting in the formation of a visible streamline of highly concentrated (and thus visible) particles.

These findings illustrate the importance of precisely engineering the channel dimensions and wall thickness in resin-based 3D-printed acoustofluidic devices to surmount the intrinsic limitations imposed by the use of low-acoustic-impedance materials. By deliberately optimizing the reflection conditions via dimensional tuning to produce a stable pressure node, single-line focusing can be reliably achieved. This consideration is in contrast to common approach to glass/silicon acoustofluidic device design space considerations owing to the ease at which focusing conditions can be established.

The native lateral (XY) resolution of a given μDLP printer is an additional consideration (in this example this is 40 μm XY-thickness, 5-500 μm Z-thickness) as it constrains both the minimum achievable feature size and the overall fidelity to a given geometry, particularly for narrow channels and sharp or delicate acoustic structures, relative to conventional microfabrication methods (i.e., soft lithography via cleanroom-fabricated molds). This fabrication process also restricts the materials library to photocurable polymeric systems (i.e., resins) resulting in devices that possess a low acoustic impedance. Thus, while fabrication of fine features is possible within these resolution limits, thin structures demonstrated increased susceptibility to damage during post processing. This was the result of the parts remaining mechanically fragile until fully cured. While this process is highly repeatable when utilizing identical materials, printer settings, and processing conditions, printed dimensions may deviate from nominal CAD dimensions. This is particularly notable in the bottom layers (i.e., those closest to the buildplate) due to compression effects that necessitate the use of a compensation factor to achieve a target thickness. This factor may vary with build-plate tolerances. Such variation may be minimized by utilizing a single build plate. As print performance can change over time, periodic characterization/calibration of both the printer and workflow is essential.

FIG. 4A is an image of an exemplary integrated acoustic mixing and focusing device, 3D-printed in resin, with three stages: mixing (red), transition (purple), and focusing (blue). FIG. 4B is a side-view schematic of an exemplary acoustic mixing and focusing device showing three stages and varying bottom (t_{bottom}) thicknesses. FIG. 1A is a 3D rendering of an exemplary integrated acoustic mixing and focusing device, with the different stages indicated by distinct colors. FIG. 4C is an image showing orange fluorescent polymer microspheres suspended in fluorescein salt solution and blue-dyed DI water co-flowed through an exemplary acoustic mixing and focusing device. FIG. 4D is an image showing a mixing region of an exemplary acoustic mixing and focusing device imaged with acoustics off and on. Acoustic activation caused the both fluids to mix, producing green fluid with scattered orange microspheres. Scale bars represent 750 μm. FIG. 4E is an image of a focusing region of an exemplary acoustic mixing and focusing device imaged with acoustics off and on. Acoustic activation aggregated the orange microspheres at the channel center, forming a single streamline. Scale bars represent 750 μm.

3D-Printing Expands the Design Space for Acoustofluidics: An Integrated, Single Piezo Device: Validating that resin-based 3D-printed microfluidic chips can independently achieve both acoustic mixing and focusing unlocks an expansive microfluidic design space for acoustofluidic devices. Harnessing the inherent design freedom of additive manufacturing to realize fully three-dimensional fluidic structures, a unique single-piezoelectric-element acoustofluidic device was demonstrated herein that merges both functionalities of mixing and focusing (FIG. 4A). This system comprises three consecutive, independent regions: (i) a mixing region, (ii) a transition stage, and (iii) a focusing region (FIGS. 4B & 1A).

Key to device operation is a 750 μm-wide internal channel sized to support the half-standing wave required for focusing a mixture of OFPM-FSS and blue-dyed tracer solution. The tₜₒₚ and sidewall thicknesses remain constant at 600 μm and 1500 μm, respectively, while the t_{bottom} thickness transitions from 1150 μm in the mixing region to 400 μm in the focusing region. This purposeful geometric modulation prevents unintended particle focusing within the mixing stage, even in the presence of sharp-edge spikes. Instead, a smoothly tapered transition region gradually reduces the base thickness to ensure continuous flow and intended device behavior.

In the absence of acoustic excitation, a clear boundary persisted between the two co-flowing fluids in the mixing zone (FIG. 4C, and FIG. 4D; “ACOUSTIC OFF”) observing only moderate diffusive mixing. Diffusive mixing progressed along the length of the channel (FIG. 4C, and FIG. 4E; “ACOUSTIC OFF”), although the microspheres remained optically undetectable given the size and concentration. Upon application of the acoustic field, the mixing region developed a uniform green hue indicating mixing of the blue and yellow streams (FIG. 4D; “ACOUSTIC ON”). In parallel, the focusing region transitions from a sparse distribution of otherwise invisible microspheres to a well-defined particle streamline (FIG. 4E “ACOUSTIC ON”).

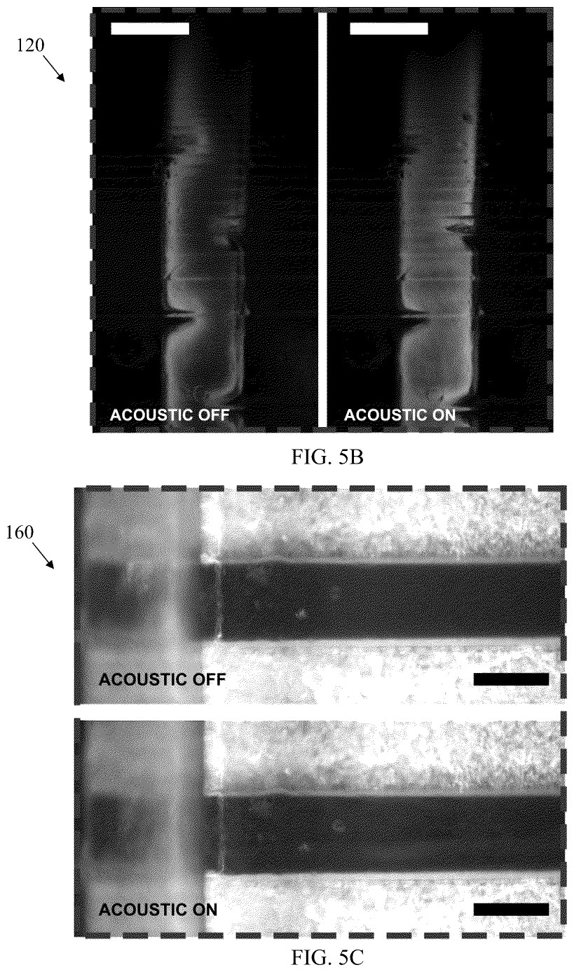

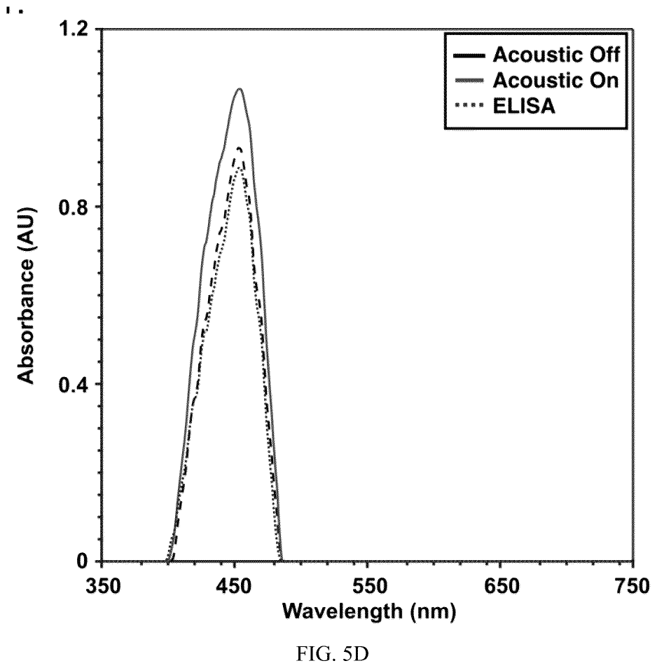

Results from this linear integrated device (FIGS. 4A, 4B, 1A, 4C, 4D and 4E) established that mixing and focusing can operate in concert under a unified piezoelectric actuation. A natural extension of this concept exploits the volumetric design freedom unique to additive manufacturing. A device with a folded channel architecture demonstrated this concept in which flow routes out of plane, traverses a curved mixing region, and returns to a downstream focusing section all within a compact footprint compatible with single-use, disposable operation (FIGS. 5A & 1B).

FIG. 5A is an image of an exemplary integrated acoustic mixing and focusing device fabricated via resin-based 3D printing comprising two stages: a mixing stage (red) and a focusing stage (blue). FIG. 1B is an image of an exemplary integrated acoustic mixing and focusing device. FIG. 5B is fluorescence images of the mixing region with acoustics off and on. Upon acoustic activation, the two fluids mix, resulting in a uniform green fluorescence signal. Scale bars represent 750 μm. FIG. 5C is bright-field images of the focusing region of an exemplary integrated acoustic mixing and focusing device with acoustics off and on. Acoustic activation aggregates the orange microspheres at the channel center, forming a single focused streamline. FIG. 1L is a schematic illustration of an exemplary enzyme-linked affinity assay and device platform. HRP is Horseradish Peroxidase, MB is magnetic bead, and STRP is streptavidin. FIG. 5D is a plot of absorbance measurements comparing standard process (ELISA), device performance in absence (Acoustic Off) and presence (Acoustic On; 20 Vpp) of acoustophoretic mixing/focusing. Increasing absorbance is proportional to increasing concentration. Scale bars represent 750 μm.

Central to this design is a curved mixing channel (radius of curvature of 5.5 mm) dimensioned to maintain laminar flow while providing sufficient path length for complete homogenization. A return loop directs the mixed effluent to a focusing channel positioned beneath the mixing section. This stacked topology would require multiple lithographic layers, precise alignment, and sequential bonding steps if fabricated via conventional methods but is formed here monolithically from via a single print. A structural air gap separates the two functional regions. The large acoustic impedance mismatch at the resin-air interface reflects incident waves and thereby isolates the resonant modes of each section, permitting independent tuning of mixing and focusing performance without geometric compromise. Smoothly graded wall thicknesses varying continuously rather than in discrete laminated steps further tailor local acoustic boundary conditions, which in turn exemplifies a class of geometric feature native to additive processes.

In the absence of acoustic excitation, the coflowing streams exhibited the expected laminar stratification with interfacial mixing limited to diffusion (FIG. 5B, “ACOUSTIC OFF”). Activation of the piezoelectric element induced vigorous streaming along the curved channel yielding a uniform fluorescent signal indicative of complete mixing (FIG. 5B, “ACOUSTIC ON”). In the downstream focusing section the suspended particles, which were initially dispersed across the channel cross-section, migrated rapidly to the central pressure node to form a tight streamline (FIG. 5C).

To assess functional relevance of the disclosed device, streptavidin-functionalized magnetic beads (MB-STRP) and biotinylated horseradish peroxidase (Biotin-HRP) were co-introduced as a model bead-based capture system. UV-Vis absorbance of the processed output (FIGS. 1L & 5D) revealed substantially elevated capture efficiency under acoustic activation. This was attributed as a direct consequence of enhanced bead-target collision frequency in the mixing zone followed by concentration of the receptor-analyte complex for downstream collection. This assay configuration mirrored the unit operations central to biomanufacturing workflows such as the affinity capture of therapeutic proteins, magnetic isolation of extracellular vesicles, and immunomagnetic selection of cells for autologous therapies. The capacity to realize such integrated, geometrically complex cartridges through rapid, iterative additive fabrication offers a route toward distributed, application-specific production platforms aligned with emerging models of personalized medicine and continuous bioprocessing.

The capability to precisely spatially engineer device and channel geometries with high precision demonstrates the versatility of 3D printing in creating complex, sophisticated acoustofluidic device architectures. By consolidating mixing and focusing in a single platform, the prototype integrated device illustrates how rational design of channel geometry and piezoelectric actuation can yield compact, multifunctional, high-performance microfluidic systems. This is a unique capability not possible in conventional glass capillary or micromachined acoustofluidic platforms.

FIGS. 6A & 6B are plots of MI at three spatial positions in the device without and with acoustic mixing for two flow rates: (FIG. 6A) 3 μL/min, (FIG. 6B) 6 μL/min. FIGS. 6C & 6D are plots showing MI at (FIG. 6C) 3 μL/min and (FIG. 6D) 6 μL/min in the region of interest over time. The magenta dashed line indicates the time of acoustic field application. FIG. 6E is an experimental image masking process used to calculate the MI within the ROI.

3D-Printed Acoustofluidics: Acoustic Mixing: Evaluation of MI can occur continuously across the length of the acoustofluidic device. For context, FIGS. 6A & 6B show the MI at three spatial positions corresponding to spike positions 5, 10, and 15 for two flow rates: 3 μL/min (FIG. 6A) and 6 μL/min (FIG. 6B). Under diffusive mixing (i.e., the absence of acoustic mixing), a fully mixed condition occurred only at an extended distance away from the device inlet for the 3 μL/min flow and did not achieve a fully mixed state at 6 μL/min. Under acoustic mixing, a fully mixed state was obtained near the entrance of the device (i.e., spike position 1). Waterfall plots for both flow conditions (3 μL/min-FIG. 6C; 6 μL/min-FIG. 6D) illustrate the dynamic variations in MI values over time and across the channel length. The region of interest (ROI) used to calculate the MI throughout the device is shown in FIG. 6E.

3D-Printed Acoustofluidics: Acoustic Focusing: Schematics of the acoustic focusing chip design from various views (e.g., front, side, top) are provided to visualize the adjusted dimensions (FIGS. 1C-1F).

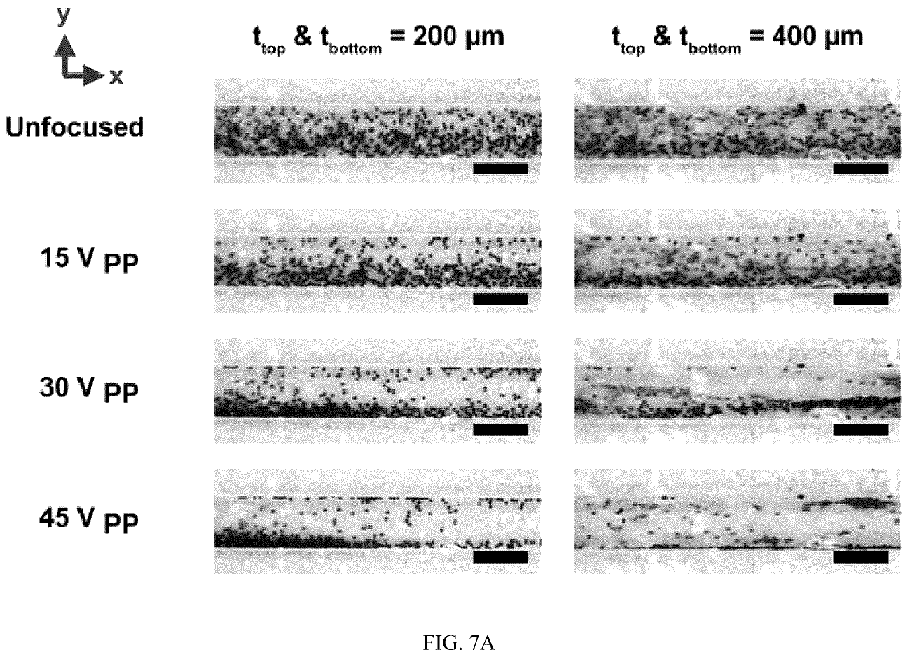

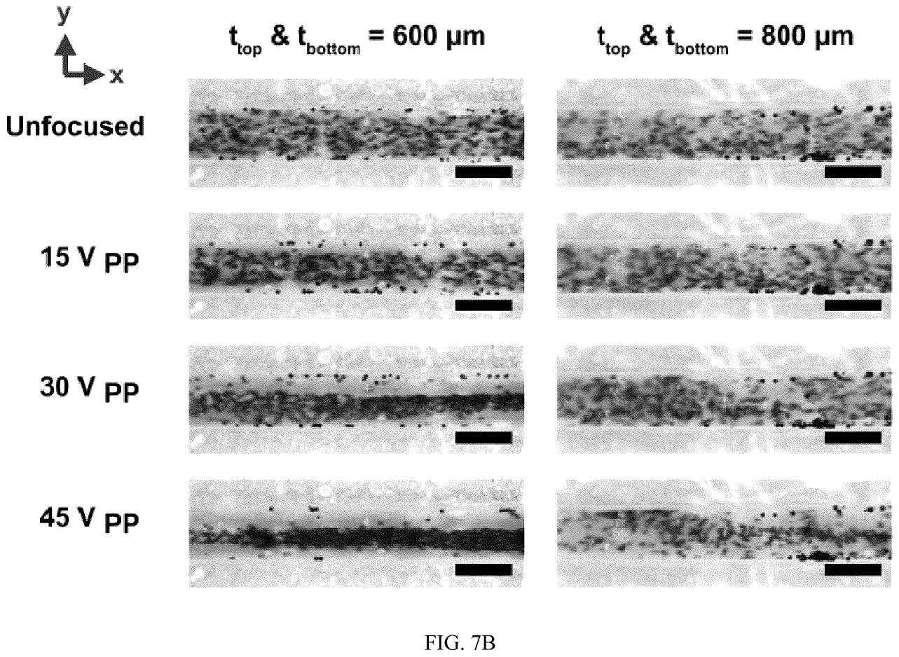

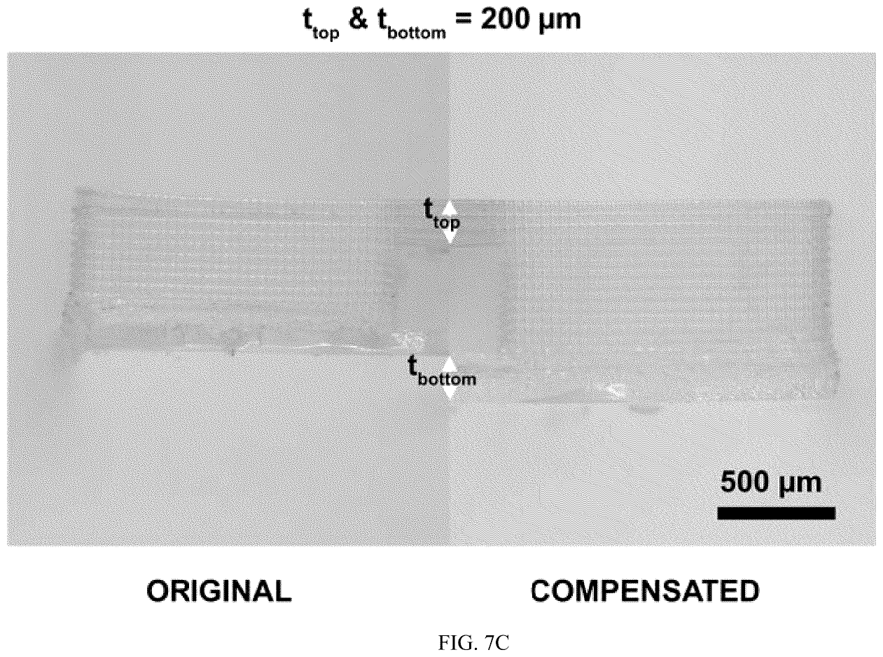

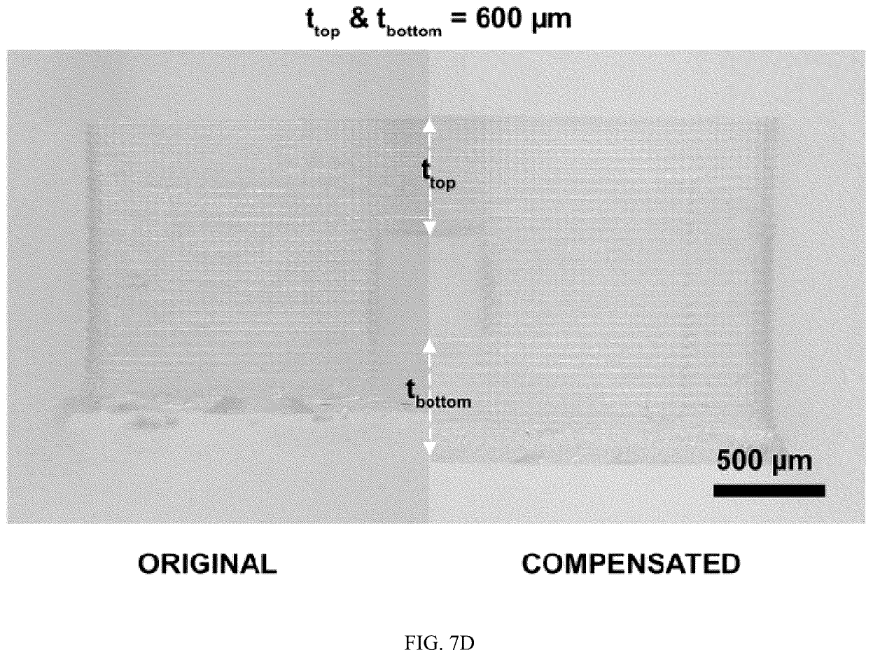

FIG. 1C is an image of an exemplary acoustic focusing chip design. FIG. 1D is an image showing a front cross-sectional view of an exemplary acoustic focusing chip. FIG. 1E is an image showing a side cross-sectional view of an exemplary acoustic focusing chip. FIG. 1F is an image showing a top cross-sectional view of an exemplary acoustic focusing chip. FIGS. 7A & 7B are images showing various top and bottom thicknesses of exemplary acoustic focusing chips experiencing different applied voltages during thickness and voltage tunings. FIGS. 7C & 7D are images showing exemplary printed chips with the original nominal and compensated thicknesses.

3D microfluidic chips with varying thicknesses (200 μm, 400 μm, 600 μm, and 800 μm) enabled investigation of the influence of device total thickness on acoustophoretic force (with voltage as analogue to acoustic energy 0 V, 15 V, 30 V, and 45 V). Black paramagnetic polyethylene microparticles (2 w/w %) suspended in silicone oil entered into a device via a syringe pump at a flow rate of 12 μL/min. As FIGS. 7A & 7B indicate, not all chips supported acoustophoretic focusing. The presence or absence of focusing depended on device thickness. Among the tested designs, chips with a nominal tₜₒₚ and t_{bottom} thickness of 600 μm exhibited the strongest focusing at 45 V (FIG. 7B).

As revealed via cross-sectional analysis, a key consideration was the occurrence of compression during the printing process of the bottom of the chip (i.e., chip interface with the build plate). FIGS. 7C & 7D highlight the critical importance of this compression factor in ensuring fabricated devices that have the as-designed channel dimensions. From the investigation it was discovered that an asymmetric tₜₒₚ and t_{bottom} thickness can significantly influence the chip's acoustic performance and is a key design parameter.

This example introduces a new class of resin-based, 3D-printed acoustofluidic devices that leverage the design freedom of additive manufacturing to enable fully integrated and multifunctional acoustic platforms. The disclosed experimental results show that careful tuning of device geometries—particularly the thickness of polymer layers above and below the fluidic channels—surmounts the intrinsic challenges posed by low-acoustic-impedance materials. In doing so, robust acoustofluidic functionality for both micromixing and single-node particle focusing was demonstrated, facilitated by half-wavelength resonance modes in entirely 3D-printed structures.

By exploiting rapid prototyping capabilities and the capacity for true three-dimensional device architectures, this approach expands the design space for acoustofluidic systems well beyond the constraints of traditional glass- and silicon-based microfabrication methods. The integrated, single-piezo device disclosed herein exemplifies how convergent fluid operations—mixing and focusing—can be unified in a compact, low-cost, and scalable format, thereby defining a blueprint for next-generation lab-on-a-chip technologies. The fundamental insights and versatile design strategies outlined in this work catalyze further development of acoustophoretic systems for applications such as point-of-care diagnostics with 3D printing serving as a key enabler of producing high-performance, customizable, and widely accessible acoustofluidic devices.

### REFERENCES

S. Zhu, F. Jiang, Y. Han, N. Xiang and Z. Ni, Analyst, 2020, 145, 7103-7124.
Y. Yang, Y. Chen, H. Tang, N. Zong and X. Jiang, Small Methods, 2020, 4, 1900451.
Y. Zhou, Y. Wu, L. Ding, X. Huang and Y. Xiong, TrAC Trends in Analytical Chemistry, 2021, 145, 116452.
H. Bruus, Lab Chip, 2011, 11, 3742.
M. Wu, A. Ozcelik, J. Rufo, Z. Wang, R. Fang and T. Jun Huang, Microsyst Nanoeng, 2019, 5, 32.
R. R. Collino, T. R. Ray, R. C. Fleming, C. H. Sasaki, H. Haj-Hariri and M. R. Begley, Extreme Mechanics Letters, 2015, 5, 37-46.
R. R. Collino, T. R. Ray, L. M. Friedrich, J. D. Cornell, C. D. Meinhart and M. R. Begley, Materials Research Letters, 2018, 6, 191-198.
Y. Chen, M. Wu, L. Ren, J. Liu, P. H. Whitley, L. Wang and T. J. Huang, Lab Chip, 2016, 16, 3466-3472.
J. Rufo, F. Cai, J. Friend, M. Wiklund and T. J. Huang, Nat Rev Methods Primers, 2022, 2, 30.
T. Laurell, F. Petersson and A. Nilsson, Chem. Soc. Rev., 2007, 36, 492-506.
J. Park, J. Kim, S. Pané, B. J. Nelson and H. Choi, Adv Healthcare Materials, 2021, 10, 2001096.
H. Xiao, M. Aliabouzar and M. L. Fabiilli, Journal of Controlled Release, 2024, 374, 205-218.
J. Xu, H. Cai, Z. Wu, X. Li, C. Tian, Z. Ao, V. C. Niu, X. Xiao, L. Jiang, M. Khodoun, M. Rothenberg, K. Mackie, J. Chen, L. P. Lee and F. Guo, Nat Commun, 2023, 14, 869.
D. S. Melchert, R. R. Collino, T. R. Ray, N. D. Dolinski, L. Friedrich, M. R. Begley and D. S. Gianola, Adv Materials Technologies, 2019, 4, 1900586.
K. Johnson, D. Melchert, D. S. Gianola, M. Begley and T. R. Ray, MRS Advances, 2021, 6, 636-643.
K. E. Johnson, B. C. Montano, K. J. Nambu, E. N. Armstrong, C. L. Cobb and M. R. Begley, Materials & Design, 2023, 234, 112328.
S. Noparast, F. Guevara Vasquez, M. Francoeur and B. Raeymaekers, Adv Materials Technologies, 2024, 9, 2301950.
M. P. Nair, A. J. T. Teo and K. H. H. Li, Micromachines, 2021, 13, 24.
M.-S. Scholz, B. W. Drinkwater and R. S. Trask, Ultrasonics, 2014, 54, 1015-1019
H. Yingbin, Mater. Horiz., 2021, 8, 885-911.
S. Saface, M. Schock, E. B. Joyee, Y. Pan and R. K. Chen, Additive Manufacturing, 2022, 51, 102642.
M. Wiklund, R. Green and M. Ohlin, Lab Chip, 2012, 12, 2438.
S. S. Sadhal, Lab Chip, 2012, 12, 2292.
N. Nama, P.-H. Huang, T. J. Huang and F. Costanzo, Biomicrofluidics, 2016, 10, 024124.
A. A. Doinikov, M. S. Gerlt, A. Pavlic and J. Dual, Microfluid Nanofluid, 2020, 24, 32.
X. Zhao, H. Chen, Y. Xiao, J. Zhang, Y. Qiu, J. Wei and N. Hao, Chemical Engineering Journal, 2022, 447, 137547.
Z. Chen, P. Liu, X. Zhao, L. Huang, Y. Xiao, Y. Zhang, J. Zhang and N. Hao, Applied Materials Today, 2021, 25, 101239.
P.-H. Huang, Y. Xie, D. Ahmed, J. Rufo, N. Nama, Y. Chen, C. Y. Chan and T. J. Huang, Lab Chip, 2013, 13, 3847.
C. Zhang, X. Guo, P. Brunet, M. Costalonga and L. Royon, Microfluid Nanofluid, 2019, 23, 104.
S. Liu, Y. Yang, Z. Ni, X. Guo, L. Luo, J. Tu, D. Zhang and J. Zhang, Sensors, 2017, 17, 1664.
Z. Liu, Y.-J. Kim, H. Wang and A. Han, The Journal of the Acoustical Society of America, 2016, 139, 332-349.
S. M. Hagsäter, A. Lenshof, P. Skafte-Pedersen, J. P. Kutter, T. Laurell and H. Bruus, Lab Chip, 2008, 8, 1178.
H. Bruus, Lab Chip, 2012, 12, 1014.
T. Laurell, F. Petersson and A. Nilsson, Chem. Soc. Rev., 2007, 36, 492-506.
A. Lenshof, C. Magnusson and T. Laurell, Lab Chip, 2012, 12, 1210.
I. Leibacher, P. Reichert and J. Dual, Lab Chip, 2015, 15, 2896-2905.
T. Laurell, F. Petersson and A. Nilsson, Chem. Soc. Rev., 2007, 36, 492-506.
P. P. Austin Suthanthiraraj, M. E. Piyasena, T. A. Woods, M. A. Naivar, G. P. López and S. W. Graves, Methods, 2012, 57, 259-271.
C. W. Shields Iv, D. F. Cruz, K. A. Ohiri, B. B. Yellen and G. P. Lopez, JoVE, 2016, 53861.
A. Fornell, T. Baasch, C. Johannesson, J. Nilsson and M. Tenje, J. Phys. D: Appl. Phys., 2021, 54, 355401.
B. Hammarström, M. Evander, H. Barbeau, M. Bruzelius, J. Larsson, T. Laurell and J. Nilsson, Lab Chip, 2010, 10, 2251.
G. Liu, J. Lei, F. Cheng, K. Li, X. Ji, Z. Huang and Z. Guo, Micromachines, 2021, 12, 876.
F. Lickert, M. Ohlin, H. Bruus and P. Ohlsson, The Journal of the Acoustical Society of America, 2021, 149, 4281-4291.
I. González, L. J. Fernández, T. E. Gómez, J. Berganzo, J. L. Soto and A. Carrato, Sensors and Actuators B: Chemical, 2010, 144, 310-317.
X. Shu, H. Liu, Y. Zhu, B. Cai, Y. Jin, Y. Wei, F. Zhou, W. Liu and S. Guo, Microfluid Nanofluid, 2018, 22, 32.
Açikgöz H. N., Karaman A., Şahin M. A., çaylan Ö. R., Büke G. C., Yildirim E., Eroğlu i. C., Erson-Bensan A. E., çetin B., Özer M. B., Ultrasonics 2023, 129, 106911.
C.-H. Wu, H. J. H. Ma, P. Baessler, R. K. Balanay and T. R. Ray, Sci. Adv., 2023, 9, eadg4272.
P. Azizian, J. Casals-Terré, J. Ricart and J. M. Cabot, Microsyst Nanoeng, 2023, 9, 91.
A. Tahmasebipour, L. Friedrich, M. Begley, H. Bruus and C. Meinhart, The Journal of the Acoustical Society of America, 2020, 148, 359-373.
A. Ozcelik, Actuators, 2022, 11, 249.
G. Cai, L. Xue, H. Zhang and J. Lin, Micromachines, 2017, 8, 274.
Z. Li, B. Zhang, D. Dang, X. Yang, W. Yang and W. Liang, Sensors and Actuators A: Physical, 2022, 344, 113757.
N. Nama, P. H. Huang, T. J. Huang and F. Costanzo, Biomicrofluidics, 2016, 10, 024124.
Z. Chen, P. Liu, X. Zhao, L. Huang, Y. Xiao, Y. Zhang, J. Zhang and N. Hao, Applied Materials Today, 2021, 25, 101239.
M. B. Özer and B. Çetin, J. Acoust. Soc. Am., 2021, 149, 2802-2812.
F. Lickert, M. Ohlin, H. Bruus and P. Ohlsson, J. Acoust. Soc. Am., 2021, 149, 4281-4291.
C. Zhang, P. Brunet, L. Royon and X. Guo, Chemical Engineering Journal, 2021, 410, 128252.
A. Lenshof, M. Evander, T. Laurell and J. Nilsson, Lab Chip, 2012, 12, 684.

The disclosures of each and every patent, patent application, and publication cited herein are hereby each incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. An acoustofluidic system, comprising
a microfluidic device comprising:
a body comprising a first end and a second end;
an inlet portion in the first end of the body comprising openings forming first and second inlets, and first and second conduits fluidly connected to the first and second inlets, respectively;
a mixing portion in the body comprising a mixing channel fluidly connected to the first and second conduits, wherein the mixing portion comprises a bottom layer, a top layer and sidewalls forming the mixing channel therein, and a plurality of protrusions extending out from the sidewalls into the interior of the mixing channel;
a focusing portion in the body comprising a focusing channel fluidly connected to the mixing channel, wherein the focusing portion comprises a bottom layer, a top layer, and sidewalls forming the focusing channel therein; and
an outlet portion in the second end of the body comprising an outlet region fluidly connected to the focusing channel, and one or more openings forming one or more outlets fluidly connected to the outlet region;
wherein a thickness of the bottom layer of the mixing portion is greater than a thickness of the bottom layer of the focusing portion; and
a transducer configured to apply acoustic energy to the microfluidic device, wherein upon application of the acoustic energy, fluid is mixed via acoustic streaming in the mixing channel, and particles are focused via a standing acoustic wave in the focusing channel.

2. The system of claim 1, wherein a thickness of the top layer of the focusing portion is greater than the thickness of the bottom layer of the focusing portion.

3. The system of claim 2, wherein a ratio between the thickness of the top layer of the focusing portion and the thickness of the bottom layer of the focusing portion is 1.5:1.

4. The system of claim 1, wherein the thickness of the bottom layer of the mixing portion is at least twice the thickness of the bottom layer of the focusing portion.

5. The system of claim 1, wherein the width of each sidewall of the focusing portion is greater than the thicknesses of the top and bottom layers of the focusing portion.

6. The system of claim 1, wherein a width of the focusing channel is selected based on at least one of an acoustic wavelength corresponding to the acoustic energy to establish the standing acoustic wave within the focusing channel, and a speed of sound of the liquid.

7. The system of claim 6, wherein the width of the focusing channel is half of the acoustic wavelength.

8. The system of claim 1, wherein the plurality of protrusions are arranged in a staggered pattern in the mixing channel.

9. The system of claim 1, wherein each protrusion in the plurality of protrusions comprises a tip angle of less than 40°.

10. The system of claim 1, further comprising a transition portion in the body comprising a transition channel fluidly connecting the mixing channel and the focusing channel, wherein the transition portion comprises a bottom layer, a top layer, and sidewalls forming the transition channel therein, and wherein the bottom layer of the transition portion tapers from a first thickness to a second thickness.

11. The system of claim 10, wherein the first thickness is the same as the thickness of the bottom layer of the mixing portion, and the second thickness is the same as the thickness of the bottom layer of the focusing portion.

12. The system of claim 1, wherein the mixing portion comprises a curved structure positioned at least partially over the focusing portion, and wherein the mixing channel extends through the curved structure out of plane of the focusing channel.

13. The system of claim 12, wherein the curved structure comprises first and second curved portions, each portion extending from a first side to a second side of the focusing portion.

14. The system of claim 1, wherein the outlet region comprises a plurality of conduits fluidly connected to the one or more outlets, and the one or more outlets comprise first and second outlets.

15. The system of claim 14, wherein a first conduit of the plurality of conduits is fluidly connected to the first outlet, and second and third conduits are fluidly connected to the second outlet.

16. The system of claim 15, wherein an opening of the first conduit is aligned with an axis extending along the length of the focusing channel, and openings of the second and third conduits are not aligned with the axis.

17. The system of claim 16, wherein at least one conduit of the plurality of conduits comprises a serpentine structure.

18. The system of claim 1, wherein the body is formed from a monolithic structure comprising a low-acoustic impedance polymer resin or a photopolymer resin fabricated via additive manufacturing.

19. The system of claim 1, further comprising a cooling block contacting at least one of the transducer and the microfluidic system.

20. The system of claim 1, wherein the transducer is configured such that a single acoustic excitation simultaneously produces acoustic streaming in the mixing channel and the standing acoustic wave in the focusing channel, wherein the standing acoustic wave is a half-standing acoustic wave.
